(19) United States
(12) Patent Application Publication
(10) Pub. No.: US 2024/0282699 A1
(43) Pub. Date: Aug. 22, 2024

(54) SEMICONDUCTOR DEVICE

(71) Applicant: ROHM CO., LTD., Kyoto (JP)

(72) Inventor: Bungo TANAKA, Kyoto (JP)

(73) Assignee: ROHM CO., LTD., Kyoto (JP)

(21) Appl. No.: 18/443,542

(22) Filed: Feb. 16, 2024

(30) Foreign Application Priority Data
Feb. 17, 2023 (JP) 2023-023610

(51) Int. Cl. H01L 23/522; H01L 23/00; H01L 23/48; H01L 23/498; H01L 25/065

(52) U.S. Cl. CPC H01L 23/5228; H01L 23/481; H01L 23/49838; H01L 24/48; H01L 25/0655; H01L 2224/48145; H01L 2224/48225; H01L 2924/181

(57) ABSTRACT

A semiconductor device includes: a substrate; an element insulating layer provided on the substrate; and a semiconductor resistance layer provided on the element insulating layer. The semiconductor resistance layer includes: a front surface side resistance layer extending in a first direction perpendicular to a thickness direction of the substrate; a substrate side resistance layer arranged closer to the substrate than the front surface side resistance layer in the thickness direction; and an internal connector that electrically connects the front surface side resistance layer and the substrate side resistance layer in series.

### CROSS-REFERENCE TO RELATED APPLICATION

This application is based upon and claims the benefit of priority from Japanese Patent Application No. 2023-023610, filed on Feb. 17, 2023, the entire contents of which are incorporated herein by reference.

### TECHNICAL FIELD

The present disclosure relates to a semiconductor device.

### BACKGROUND

As an example of a semiconductor device, there is a known configuration that includes a semiconductor substrate, an insulating layer formed on the semiconductor substrate, and a semiconductor resistance layer formed on the insulating layer.

### BRIEF DESCRIPTION OF DRAWINGS

The accompanying drawings, which are incorporated in and constitute a part of the specification, illustrate embodiments of the present disclosure.

FIG. 1 is a schematic plan view of a semiconductor module according to a first embodiment.

FIG. 2 is a schematic plan view of a first chip and a second chip in the semiconductor module of FIG. 1.

FIG. 3 is a schematic plan view of a semiconductor resistance layer in the first chip.

FIG. 4 is an enlarged view of a frame A1 of FIG. 3.

FIG. 5 is a schematic cross-sectional view of the first chip, which is taken along line F5-F5 of FIG. 4.

FIG. 6 is a schematic cross-sectional view of the first chip, which is taken along line F6-F6 of FIG. 3.

FIG. 7 is a schematic plan view of a portion of the semiconductor resistance layer of FIG. 3.

FIG. 8 is a schematic cross-sectional view of the first chip, which is taken along line F8-F8 of FIG. 7.

FIG. 9 is a schematic cross-sectional view of the first chip, which is taken along line F9-F9 of FIG. 7.

FIG. 10 is a schematic cross-sectional view of the first chip, which is taken along line F10-F10 of FIG. 7.

FIG. 11 is a schematic cross-sectional view showing an example of a process of manufacturing the first chip according to the first embodiment.

FIG. 12 is a schematic cross-sectional view of a wiring layer and its surroundings, and shows a manufacturing process subsequent to FIG. 11.

FIG. 13 is a schematic cross-sectional view of a wiring layer different from that in FIG. 12 and its surroundings, and shows a manufacturing process subsequent to FIG. 12.

FIG. 14 is a schematic cross-sectional view showing a manufacturing process subsequent to FIG. 13.

FIG. 15 is a schematic cross-sectional view showing a manufacturing process subsequent to FIG. 14.

FIG. 16 is a schematic cross-sectional view showing a manufacturing process subsequent to FIG. 15.

FIG. 17 is a schematic cross-sectional view showing a manufacturing process subsequent to FIG. 16.

FIG. 18 is a schematic cross-sectional view showing a manufacturing process subsequent to FIG. 17.

FIG. 19 is a schematic plan view of a plurality of semiconductor resistance layers and their surroundings in a first chip according to a second embodiment.

FIG. 20 is a schematic cross-sectional view of the first chip, which is taken along line F20-F20 of FIG. 19.

FIG. 21 is a schematic plan view of a plurality of semiconductor resistance layers and their surroundings in a first chip according to a third embodiment.

FIG. 22 is a schematic cross-sectional view of the first chip, which is taken along line F22-F22 of FIG. 21.

FIG. 23 is a schematic cross-sectional view of the first chip, which is taken along line F23-F23 of FIG. 21.

FIG. 24 is a schematic plan view of a plurality of semiconductor resistance layers and their surroundings in a first chip according to a fourth embodiment.

FIG. 25 is a schematic cross-sectional view of the first chip, which is taken along line F25-F25 of FIG. 24.

FIG. 26 is a schematic cross-sectional view of the first chip, which is taken along line F26-F26 of FIG. 24.

FIG. 27 is a schematic cross-sectional view of the first chip, which is taken along line F27-F27 of FIG. 24.

FIG. 28 is a schematic plan view of a plurality of semiconductor resistance layers and their surroundings in a first chip according to a fifth embodiment.

FIG. 29 is a schematic plan view of resistance layers on a side of a substrate in the plurality of semiconductor resistance layers.

FIG. 30 is a schematic cross-sectional view of the first chip, which is taken along line F30-F30 of FIG. 28.

FIG. 31 is a schematic cross-sectional view of the first chip, which is taken along line F31-F31 of FIG. 28.

FIG. 32 is a schematic cross-sectional view of the first chip, which is taken along line F32-F32 of FIG. 28.

FIG. 33 is a schematic plan view of a plurality of semiconductor resistance layers and their surroundings in a first chip according to a sixth embodiment.

FIG. 34 is a schematic cross-sectional view of the first chip, which is taken along line F34-F34 of FIG. 33.

FIG. 35 is a schematic cross-sectional view of the first chip, which is taken along line F35-F35 of FIG. 33.

FIG. 36 is a schematic cross-sectional view of the first chip, which is taken along line F36-F36 of FIG. 33.

FIG. 37 is a schematic cross-sectional view of a first chip according to a modification.

FIG. 38 is a schematic plan view of a plurality of semiconductor resistance layers and their surroundings in a first chip according to a modification.

FIG. 39 is a schematic plan view of a plurality of semiconductor resistance layers and their surroundings in a first chip according to a modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, some embodiments of a semiconductor device and a semiconductor module according to the present disclosure will be described with reference to the accompanying drawings. It should be noted that, for simplicity and clarity of explanation, components shown in the drawings are not necessarily drawn to scale. Further, in order to facilitate understanding, hatching lines may be omitted in cross-sectional views. The accompanying drawings merely illustrate embodiments of the present disclosure and should not be considered as limiting the present disclosure.

The following detailed description includes devices, systems, and methods embodying exemplary embodiments of the present disclosure. This detailed description is for illustrative purposes only and is not intended to limit the embodiments of the present disclosure or the applications and uses of such embodiments.

### First Embodiment

### [Configuration of Semiconductor Module]

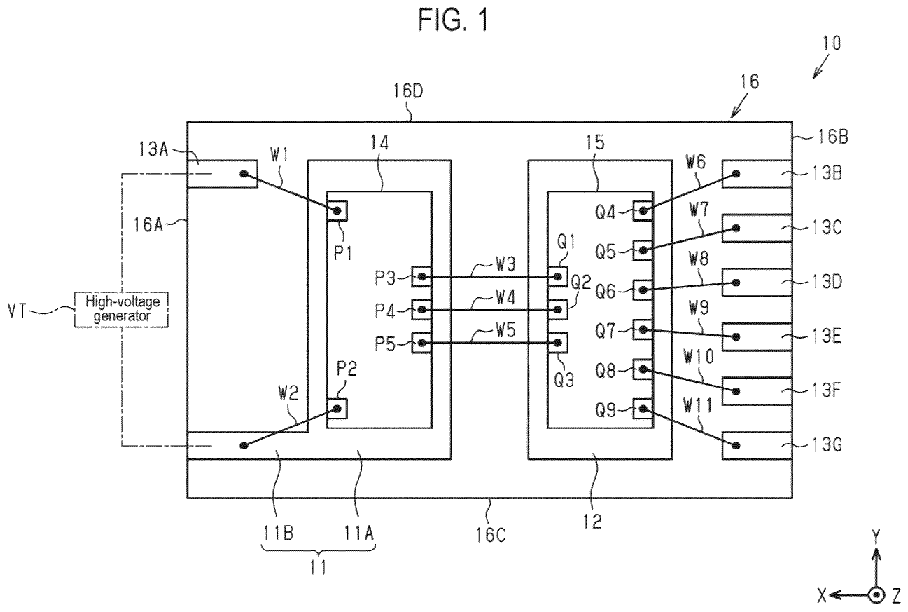

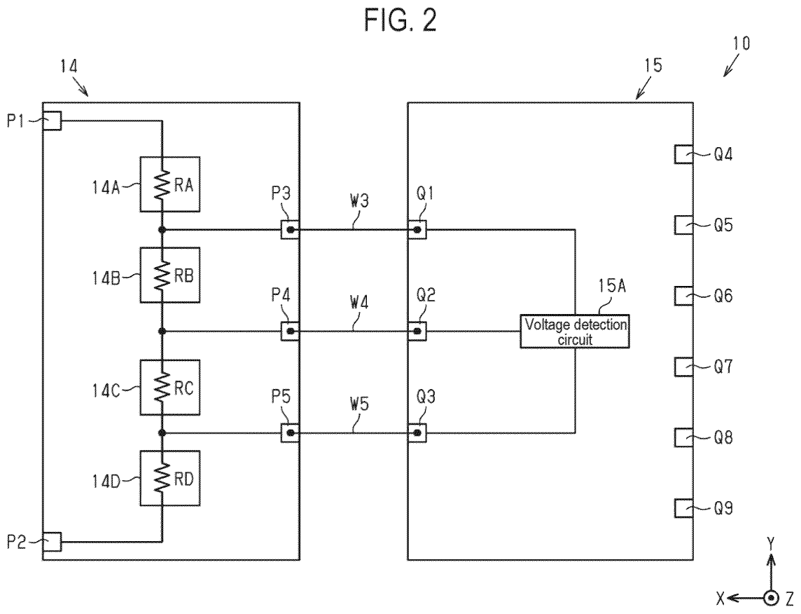

A configuration of a semiconductor module 10 according to a first embodiment will be described with reference to FIGS. 1 and 2. FIG. 1 schematically shows an overall arrangement configuration of the semiconductor module 10. FIG. 2 schematically shows an electrical configuration and electrical connection configuration of each of a first chip 14 and a second chip 15, which will be described later, of the semiconductor module 10. Further, in FIG. 1, for ease of understanding the figure, internal constituent elements of a sealing resin 16, which will be described later, are shown with solid lines. In FIG. 2, for ease of understanding the figure, internal constituent elements of the first chip 14 and the second chip 15 are shown with solid lines.

The term “in a plan view” used in the present disclosure refers to viewing the semiconductor module 10 in a Z direction of mutually orthogonal XYZ axes shown in FIG. 1. Unless otherwise specified, “in a plan view” refers to viewing the semiconductor module 10 from above along the Z-axis.

As shown in FIG. 1, the semiconductor module 10 includes a frame 11, a die pad 12, a plurality of (seven in the first embodiment) leads 13A to 13G, the first chip 14 mounted on the frame 11, the second chip 15 mounted on the die pad 12, wires W1 to W11, and the sealing resin 16 for sealing those described above. Here, in the present disclosure, the first chip 14 corresponds to a “semiconductor device” and the frame 11 corresponds to a “support.”

The sealing resin 16 is formed, for example, in a rectangular flat plate shape with the Z direction as a thickness direction. The sealing resin 16 has first to fourth sealing side surfaces 16A to 16D. In the example shown in FIG. 1, the sealing resin 16 is formed in a rectangular shape with an X direction being a longitudinal direction and a Y direction being a lateral direction in a plan view. The first sealing side surface 16A and the second sealing side surface 16B constitute both end surfaces of the sealing resin 16 in the X direction, and the third sealing side surface 16C and the fourth sealing side surface 16D constitute both end surfaces of the sealing resin 16 in the Y direction. The shape of the sealing resin 16 in a plan view can be arbitrarily changed. In one example, the shape of the sealing resin 16 in a plan view may be square.

The frame 11, the die pad 12, and the leads 13A to 13G are arranged to be spaced apart from one another in the X direction. In other words, the X direction is an arrangement direction of the frame 11, the die pad 12, and the leads 13A to 13G. In the example shown in FIG. 1, the arrangement direction of the frame 11, the die pad 12, and the leads 13A to 13G coincides with the longitudinal direction of the sealing resin 16. Therefore, it can be said that the frame 11, the die pad 12, and the leads 13A to 13G are arranged to be spaced apart from one another in the longitudinal direction of the sealing resin 16. The frame 11 is arranged closer to the first sealing side surface 16A than the die pad 12. The leads 13A to 13G are arranged closer to the second sealing side surface 16B than the die pad 12. That is, the die pad 12 is arranged between the frame 11 and the leads 13A to 13G in the X direction. The frame 11, the die pad 12, and the leads 13A to 13G are each made of a metallic material such as copper (Cu) or aluminum (Al).

Here, in the first embodiment, the frame 11, the die pad 12, and the leads 13A to 13G are each formed of a thin metal plate. The frame 11 has the first chip 14 mounted thereon and is electrically connected to the first chip 14. The second chip 15 is mounted on the die pad 12, and the leads 13A to 13G are electrically connected to the second chip 15. Therefore, the frame 11 and the leads 13A to 13G are not limited to thin metal plates, but may be any conductive layer. Further, the die pad 12 is not limited to a conductive material such as a thin metal plate, but may be a plate material made of an insulating material. That is, the die pad 12 may be any support that supports the second chip 15.

The frame 11 includes a die pad portion 11A and a lead portion 11B. In the first embodiment, the die pad portion 11A and the lead portion 11B are integrally formed. The die pad portion 11A is a portion on which the first chip 14 is mounted, and supports the first chip 14. The die pad portion 11A is arranged closer to the first sealing side surface 16A than a center of the sealing resin 16 in the X direction. On the other hand, the die pad portion 11A is arranged to be spaced apart from the first sealing side surface 16A toward the second sealing side surface 16B in the X direction. The die pad portion 11A is formed in a rectangular flat plate shape with the Z direction as a thickness direction. A shape of the die pad portion 11A in a plan view is a rectangular shape in which the Y direction is a longitudinal direction and the X direction is a lateral direction. In other words, the die pad portion 11A is formed such that the arrangement direction of the frame 11, the die pad 12, and the leads 13A to 13G is the lateral direction. It can also be said that the die pad portion 11A is formed such that the longitudinal direction of the sealing resin 16 is the lateral direction.

The first chip 14 is mounted on the die pad portion 11A. More specifically, the first chip 14 is bonded to the die pad portion 11A by a conductive bonding material such as solder paste or silver (Ag) paste. It can also be said that the first chip 14 is die-bonded to the die pad portion 11A. As described above, it can be said that the first chip 14 is mounted on the frame 11.

The lead portion 11B is connected to a corner portion consisting of an end portion, which is closer to the third sealing side surface 16C, of both end portions of the die pad portion 11A in the Y direction, and an end portion, which is closer to the first sealing side surface 16A, of both end portions of the die pad portion 11A in the X direction. In the example of FIG. 1, the lead portion 11B extends along the X direction from the die pad portion 11A toward the first sealing side surface 16A.

Further, a configuration of the frame 11 can be changed arbitrarily and, for example, the die pad portion 11A and the lead portion 11B may be provided separately. In other words, the die pad portion 11A and the lead portion 11B may be arranged to be spaced apart from each other. In this case, the die pad portion 11A is not limited to a thin metal plate (conductive layer), and may be made of an insulating material. That is, the die pad 12 may be any support that supports the first chip 14.

The die pad 12 is a portion on which the second chip 15 is mounted, and supports the second chip 15. A shape of the die pad 12 in a plan view is a rectangular shape in which the Y direction is a longitudinal direction and the X direction is a lateral direction. Therefore, the longitudinal direction of the die pad 12 coincides with the longitudinal direction of the die pad portion 11A of the frame 11, and the lateral direction of the die pad 12 coincides with the lateral direction of the die pad portion 11A. That is, the die pad 12 is formed such that the arrangement direction of the frame 11, the die pad 12, and the leads 13A to 13G is the lateral direction. It can also be said that the die pad 12 is formed such that the longitudinal direction of the sealing resin 16 is the lateral direction.

The second chip 15 is mounted on the die pad 12. More specifically, the second chip 15 is bonded to the die pad 12 by a conductive bonding material such as solder paste or silver paste. It can also be said that the second chip 15 is die-bonded to the die pad 12.

The lead 13A and the leads 13B to 13G are arranged in a distributed manner at both end portions of the sealing resin 16 in the X direction. More specifically, the lead 13A is arranged at the end portion, which is closer to the first sealing side surface 16A, of both end portions of the sealing resin 16 in the X direction. Each of the leads 13B to 13G is arranged at the end portion, which is closer to the second sealing side surface 16B, of both end portions of the sealing resin 16 in the X direction. In the first embodiment, the lead 13A is arranged at a position overlapping with an end portion, which is closer to the fourth sealing side surface 16D, of both end portions of the die pad portion 11A in the Y direction when viewed from the X direction. The lead 13A is arranged closer to the first sealing side surface 16A than the die pad portion 11A and spaced apart from the die pad portion 11A.

The leads 13B to 13G are arranged to be aligned with one another in the X direction and spaced apart from one another in the Y direction. The leads 13B to 13G are arranged in the order of the lead 13B, the lead 13C, the lead 13D, the lead 13E, the lead 13F, and the lead 13G from the fourth sealing side surface 16D toward the third sealing side surface 16C. As can be seen from FIG. 1, a distance between the lead 13A and the lead portion 11B in the Y direction is larger than a distance between adjacent leads in the Y direction among the leads 13B to 13G.

The first chip 14 mounted on the die pad portion 11A is formed in a rectangular flat plate shape with the Z direction as a thickness direction. A shape of the first chip 14 in a plan view is a rectangular shape with a longitudinal direction being the Y direction and with a lateral direction being the X direction. That is, the longitudinal direction of the first chip 14 coincides with the longitudinal direction of the die pad portion 11A, and the lateral direction of the first chip 14 coincides with the lateral direction of the die pad portion 11A. Therefore, the first chip 14 is arranged such that its lateral direction coincides with the arrangement direction of the frame 11, the die pad 12, and the leads 13A to 13G. It can also be said that the first chip 14 is arranged such that its lateral direction coincides with the longitudinal direction of the sealing resin 16. Further, the shape and arrangement of the first chip 14 in a plan view can be changed arbitrarily.

The first chip 14 includes a plurality of terminals P1 to P5. The terminals P1 to P5 are formed to be exposed from a chip surface of the first chip 14. The terminals P1 and P2 are provided at an end portion, which is closer to the first sealing side surface 16A, of both end portions of the chip surface in the X direction. The terminal P1 is provided near the lead 13A on the chip surface. The terminal P2 is provided near the lead portion 11B on the chip surface. The terminals P3 to P5 are provided at an end portion, which is closer to the second chip 15, of both end portions of the chip surface in the X direction. The terminals P3 to P5 are arranged to be spaced apart from one another in the Y direction. Further, the number of terminals of the first chip 14 can be changed arbitrarily. Further, the arrangement positions of the terminals P1 to P5 can be changed arbitrarily. In one example, at least one of the terminal P1 or the terminal P2 may be arranged at the end portion, which is closer to the second chip 15, of both end portions of the first chip 14 in the X direction.

The second chip 15 mounted on the die pad 12 is formed in a rectangular flat plate shape with the Z direction as a thickness direction. A shape of the second chip 15 in a plan view is a rectangular shape with a longitudinal direction being the Y direction and with a lateral direction being the X direction. That is, the longitudinal direction of the second chip 15 coincides with the longitudinal direction of the die pad 12, and the lateral direction of the second chip 15 coincides with the lateral direction of the die pad 12. Therefore, the second chip 15 is arranged such that its lateral direction coincides with the arrangement direction of the frame 11, the die pad 12, and the leads 13A to 13G. It can also be said that the second chip 15 is arranged such that its lateral direction coincides with the longitudinal direction of the sealing resin 16. Further, the shape and arrangement of the second chip 15 in a plan view can be changed arbitrarily.

The second chip 15 includes a plurality of terminals Q1 to Q9. The terminals Q1 to Q9 are formed to be exposed from a chip surface of the second chip 15. The terminals Q1 to Q3 are provided at an end portion, which is closer to the first chip 14, of both end portions of the chip surface in the X direction. The terminals Q1 to Q3 are arranged to be spaced apart from one another in the Y direction. The terminals Q4 to Q9 are provided at an end portion, which is closer to the second sealing side surface 16B (the leads 13B to 13G), of both end portions of the chip surface in the X direction. The terminals Q4 to Q9 are arranged to be spaced apart from one another in the Y direction. In addition, the number of terminals of the second chip 15 can be changed arbitrarily.

The terminal P1 of the first chip 14 is electrically connected to the lead 13A by a wire W1. The terminal P2 is electrically connected to the lead portion 11B by a wire W2. Therefore, it can be said that the terminal P2 is electrically connected to the frame 11. A high-voltage generator VT is electrically connected to the lead 13A and the lead portion 11B. The high-voltage generator VT is, for example, a DC power supply. A positive electrode of the high-voltage generator VT is electrically connected to the lead 13A, and a negative electrode of the high-voltage generator VT is electrically connected to the lead portion 11B.

The terminals P3 to P5 of the first chip 14 are individually and electrically connected to the terminals Q1 to Q3 of the second chip 15 by wires W3 to W5. The terminals Q4 to Q9 are individually and electrically connected to the leads 13B to 13G by wires W6 to W11.

Here, in the first embodiment, among the terminals P1 to P5, the terminals P1 and P2 constitute high-voltage side terminals, and the terminals P3 to P5 constitute low-voltage side terminals. That is, among the terminals P1 to P5 of the first chip 14, terminals electrically connected to the lead 13A and the lead portion 11B constitute the high-voltage side terminals, and terminals electrically connected to the second chip 15 constitute the low-voltage side terminals.

As described above, the die pad portion 11A of the frame 11 electrically connected to the high-voltage generator VT constitutes a high-voltage side die pad, and the die pad 12 constitutes a low-voltage side die pad. Therefore, a dielectric breakdown voltage between the terminals P3 to P5 and a substrate 30, which will be described later, of the first chip 14 is higher than a dielectric breakdown voltage between the terminals P1 and P2 and the substrate 30. In one example, the dielectric breakdown voltage between the terminals P3 to P5 and the substrate 30 is about 3,850 V in DC voltage, and the dielectric breakdown voltage between the terminals P1 and P2 and the substrate 30 is about 1,400 V in DC voltage.

Next, internal circuit configurations of the first chip 14 and the second chip 15 will be described. As shown in FIG. 2, the first chip 14 includes first to fourth resistance circuits 14A to 14D for stepping-down a high voltage of the high-voltage generator VT (see FIG. 1). The first resistance circuit 14A has a resistance value RA, the second resistance circuit 14B has a resistance value RB, the third resistance circuit 14C has a resistance value RC, and the fourth resistance circuit 14D has a resistance value RD.

The resistance value RB is smaller than the resistance value RA. A ratio (RB/RA) of the resistance value RB to the resistance value RA is set in advance. The resistance value RC is smaller than the resistance value RD. A ratio (RC/RD) of the resistance value RC to the resistance value RD is set in advance. The ratio (RB/RA) and the ratio (RC/RD) are set to be a same predetermined value (for example, 1/999).

The first to fourth resistance circuits 14A to 14D are connected in series. Each of the first to fourth resistance circuits 14A to 14D has a first end portion and a second end portion. The first end portion of the first resistance circuit 14A is electrically connected to the terminal P1, and the second end portion of the first resistance circuit 14A is electrically connected to the first end portion of the second resistance circuit 14B. A connection point between the first resistance circuit 14A and the second resistance circuit 14B is electrically connected to the terminal P3. The second end portion of the second resistance circuit 14B is electrically connected to the first end portion of the third resistance circuit 14C. A connection point between the second resistance circuit 14B and the third resistance circuit 14C is electrically connected to the terminal P4. The second end portion of the third resistance circuit 14C is electrically connected to the first end portion of the fourth resistance circuit 14D. A connection point between the third resistance circuit 14C and the fourth resistance circuit 14D is electrically connected to the terminal P5. The second end portion of the fourth resistance circuit 14D is electrically connected to the terminal P2.

The second chip 15 includes a voltage detection circuit 15A. The voltage detection circuit 15A includes an operational amplifier. The voltage detection circuit 15A is electrically connected to the terminals Q1 to Q3. The terminal Q1 is electrically connected to the terminal P3 of the first chip 14 by the wire W3, the terminal Q2 is electrically connected to the terminal P4 of the first chip 14 by the wire W4, and the terminal Q3 is electrically connected to the terminal P5 of the first chip 14 by the wire W5. Therefore, the voltage detection circuit 15A is configured to detect voltages between the connection point between the first resistance circuit 14A and the second resistance circuit 14B, the connection point between the second resistance circuit 14B and the third resistance circuit 14C, and the connection point between the third resistance circuit 14C and the fourth resistance circuit 14D. The terminals Q4 to Q9 (the leads 13B to 13G (see FIG. 1)) are used to supply a power supply voltage to the operational amplifier in the second chip 15 and to output an output signal of the voltage detection circuit 15A.

### [Schematic Planar Structure of First Chip]

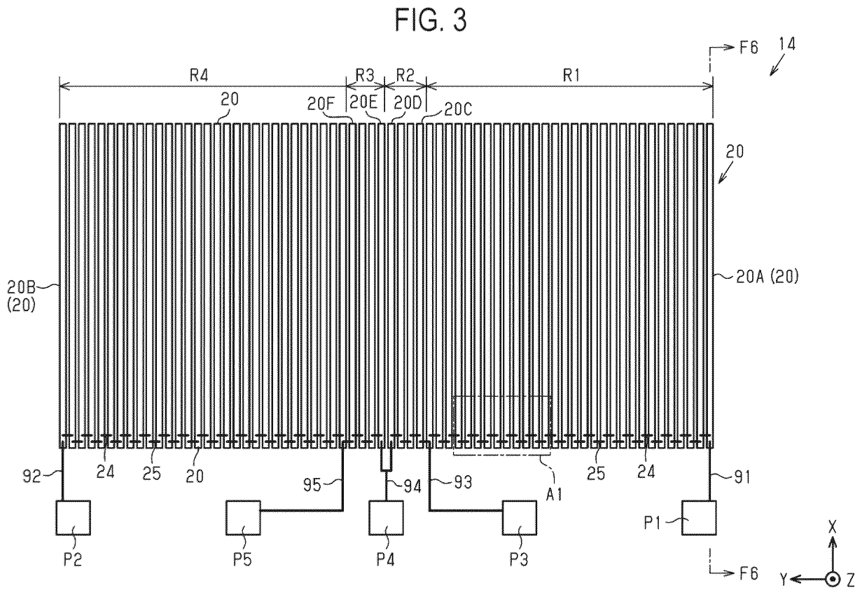

FIG. 3 shows an example of a schematic planar structure of the first chip 14 including the first to fourth resistance circuits 14A to 14D (see FIG. 2). Further, FIG. 3 shows an example in which the terminals P1 and P2 are arranged on the same side as the terminals P3 to P5 for ease of understanding the figure. As shown in FIG. 1, the terminals P1 and P2 may be arranged on an opposite side of the first chip 14 from the terminals P3 to P5 in the X direction.

As shown in FIG. 3, the first chip 14 includes a plurality of unit semiconductor resistance layers (hereinafter referred to as “semiconductor resistance layers 20”). Each semiconductor resistance layer 20 extends along the X direction in a plan view. In other words, each semiconductor resistance layer 20 extends along the lateral direction of the first chip 14 in a plan view. In a plan view, the semiconductor resistance layers 20 are arranged to be aligned with one another in the X direction and spaced apart from one another in the Y direction. In other words, in a plan view, the semiconductor resistance layers 20 are arranged to be aligned with one another in the lateral direction of the first chip 14 and spaced apart from one another in the longitudinal direction of the first chip 14. The semiconductor resistance layers 20 are electrically connected in series.

The terminal P1 is electrically connected to a semiconductor resistance layer 20A arranged at a first end in the Y direction, among the plurality of semiconductor resistance layers 20. The terminal P2 is electrically connected to a semiconductor resistance layer 20B arranged at a second end opposite to the first end in the Y direction, among the plurality of semiconductor resistance layers 20. The terminal P1 and the semiconductor resistance layer 20A are electrically connected to each other by a wiring layer 91. The terminal P2 and the semiconductor resistance layer 20B are electrically connected to each other by a wiring layer 92.

The semiconductor resistance layers 20 are used as constituent elements of the first to fourth resistance circuits 14A to 14D. The semiconductor resistance layers 20 can be divided into first to fourth resistance regions R1 to R4 as a plurality of resistance regions in the Y direction. That is, the first to fourth resistance regions R1 to R4 are regions divided in the longitudinal direction of the first chip 14. The first resistance region R1 is a region including the first end of the plurality of semiconductor resistance layers 20 in the Y direction. In other words, the first resistance region R1 is a region of an end portion in the Y direction that includes the semiconductor resistance layer 20A. The fourth resistance region R4 is a region including the second end of the plurality of semiconductor resistance layers 20 in the Y direction. In other words, the fourth resistance region R4 is a region of an end portion in the Y direction that includes the semiconductor resistance layer 20B. A portion of the plurality of semiconductor resistance layers 20 located between the first resistance region R1 and the fourth resistance region R4 in the Y direction is divided into the second resistance region R2 and the third resistance region R3. The second resistance region R2 is a region adjacent to the first resistance region R1, and the third resistance region R3 is a region adjacent to the fourth resistance region R4. Therefore, the first to fourth resistance regions R1 to R4 are arranged in the order of the resistance regions R1, R2, R3, and R4 from the first end (the semiconductor resistance layer 20A) to the second end (the semiconductor resistance layer 20B) of the plurality of semiconductor resistance layers 20. The first resistance region R1 is a region forming the first resistance circuit 14A, the second resistance region R2 is a region forming the second resistance circuit 14B, the third resistance region R3 is a region forming the third resistance circuit 14C, and the fourth resistance region R4 is a region forming the fourth resistance circuit 14D.

The terminal P3 is electrically connected to a semiconductor resistance layer 20C at an end near the first resistance region R1 among the plurality of semiconductor resistance layers 20 in the second resistance region R2. The terminal P3 and the semiconductor resistance layer 20C are electrically connected to each other by a wiring layer 93.

The terminal P4 is electrically connected to a semiconductor resistance layer 20D at an end near the third resistance region R3 among the plurality of semiconductor resistance layers 20 in the second resistance region R2, and a semiconductor resistance layer 20E at an end near the second resistance region R2 among the plurality of semiconductor resistance layers 20 in the third resistance region R3. The terminal P4 and the semiconductor resistance layers 20D and 20E are electrically connected to each other by a wiring layer 94.

The terminal P5 is electrically connected to a semiconductor resistance layer 20F at the end near the fourth resistance region R4 among the plurality of semiconductor resistance layers 20 in the third resistance region R3. The terminal P5 and the semiconductor resistance layer 20F are electrically connected to each other by a wiring layer 95.

The number of semiconductor resistance layers 20 in each of the first to fourth resistance regions R1 to R4 is individually set. In the first embodiment, the number of semiconductor resistance layers 20 in the first resistance region R1 and the number of semiconductor resistance layers 20 in the fourth resistance region R4 are the same, and the number of semiconductor resistance layers 20 in the second resistance region R2 and the number of semiconductor resistance layers 20 in the third resistance region R3 are the same. The number of semiconductor resistance layers 20 in each of the first resistance region R1 and the fourth resistance region R4 is larger than the number of semiconductor resistance layers 20 in each of the second resistance region R2 and the third resistance region R3. Further, the number of semiconductor resistance layers 20 in each of the first to fourth resistance regions R1 to R4 is not limited to that in the first embodiment, and can be changed arbitrarily.

### [Internal Structure of First Chip]

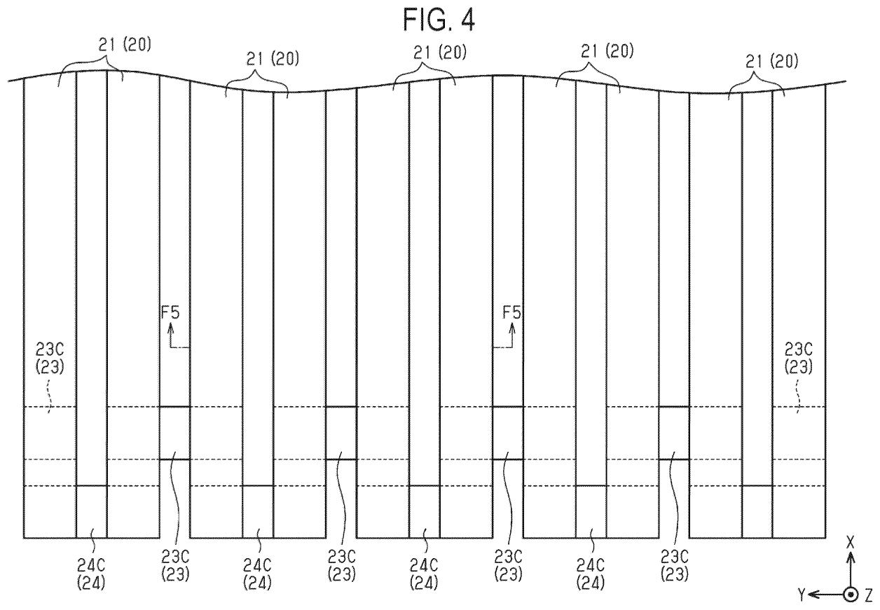

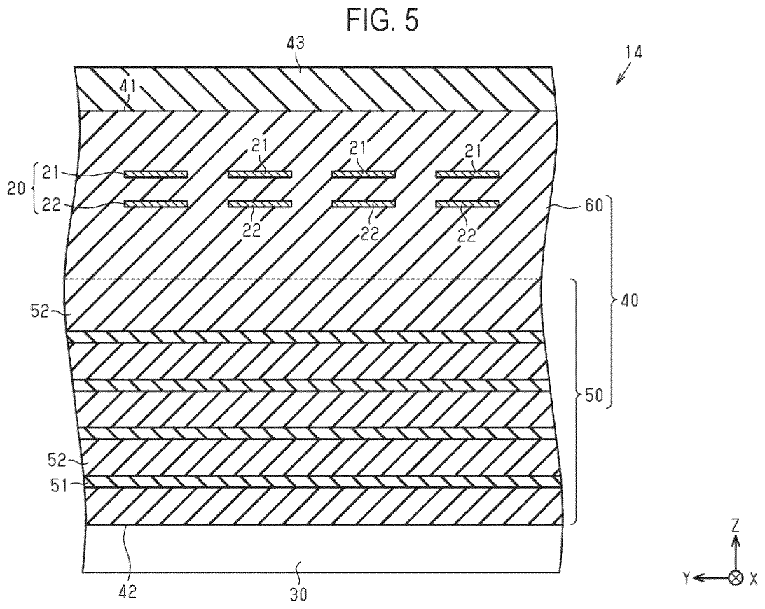

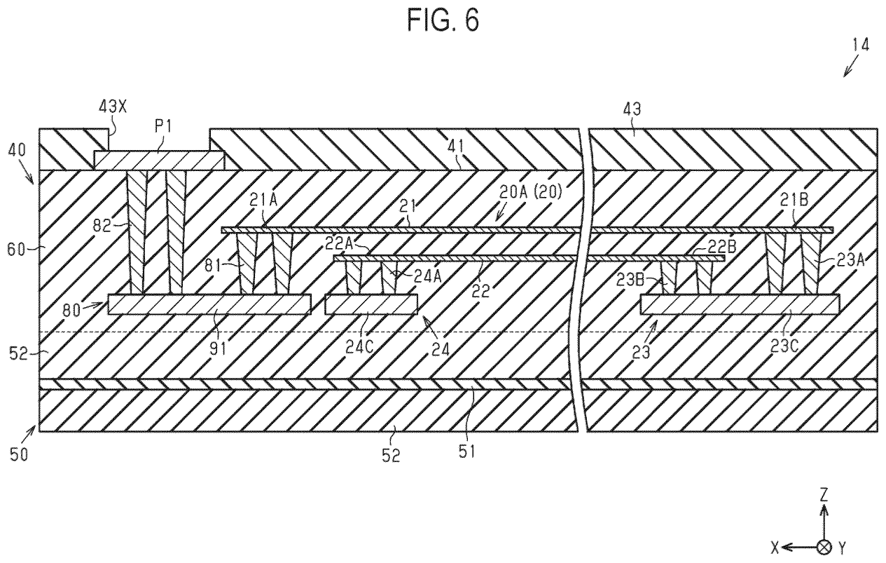

An example of an internal configuration of the first chip 14 will be described with reference to FIGS. 4 to 6. FIG. 4 is an enlarged plan view of a frame A1 indicated by a one-dot chain line of FIG. 3. FIG. 5 schematically shows a cross-sectional structure of the first chip 14, which is taken along line F5-F5 of FIG. 4. FIG. 6 schematically shows a cross-sectional structure of the first chip 14, which is taken along line F6-F6 of FIG. 3. Further, for the sake of convenience of explanation, FIG. 5 shows an interface between a substrate side insulating layer 50 and a front surface side insulating layer 60 which will be described later. Actually, the interface between the substrate side insulating layer 50 and the front surface side insulating layer 60 may not be visible. Further, in FIG. 6, a portion of the substrate side insulating layer 50 and the substrate 30 are omitted.

As shown in FIG. 5, the first chip 14 includes the substrate 30 and an element insulating layer 40 formed on the substrate 30. The substrate 30 is a semiconductor substrate formed of a material containing, for example, Si (silicon). A thickness of the substrate 30 is, for example, about 300 μm. Further, the substrate 30 may be formed of a wide band gap semiconductor or a compound semiconductor. The wide band gap semiconductor is a semiconductor substrate having a band gap of 2.0 eV or more. The wide band gap semiconductor may be SiC (silicon carbide). The compound semiconductor may be a group III-V compound semiconductor. The compound semiconductor may include at least one of AlN (aluminum nitride), InN (indium nitride), GaN (gallium nitride), or GaAs (gallium arsenide).

The element insulating layer 40 has an element front surface 41 and an element back surface 42 facing opposite to each other in the Z direction. Here, in the first embodiment, the Z direction corresponds to a “thickness direction of the element insulating layer.” The element back surface 42 is in contact with the substrate 30. The element front surface 41 is a surface opposite to the substrate 30 in the Z direction.

As shown in FIG. 6, the terminals P1 to P5 (see FIG. 3) and a passivation film 43 are formed on the element insulating layer 40. The terminals P1 to P5 are formed on the element front surface 41 of the element insulating layer 40. The terminals P1 to P5 are made of one or more selected as appropriate from Ti (titanium), TiN (titanium nitride), Ta (tantalum), TaN (tantalum nitride), Au (gold), Ag, Cu, Al, Ni (nickel), Pd (palladium), and W (tungsten). In the first embodiment, the terminals P1 to P5 are formed of a material containing Al. As an example, FIG. 6 shows a structure in which the terminal P1 is formed on the element front surface 41.

The terminal P1 is covered with the passivation film 43. On the other hand, the passivation film 43 has an opening 43X that exposes the terminal P1. Although not shown, a relationship between the terminals P2 to P5 and the passivation film 43 is the same as a relationship between the terminal P1 and the passivation film 43. As described above, the terminals P1 to P5 constitute electrode pads.

The passivation film 43 formed on the element front surface 41 of the element insulating layer 40 is a surface protection film of the first chip 14. The passivation film 43 is formed of a material containing, for example, SiN. Further, the material forming the passivation film 43 can be changed arbitrarily, and may be formed of a material containing, for example, SiO₂ (silicon oxide). Further, the passivation film 43 may have a stacked structure of a plurality of films, for example, a stacked structure of a film formed of a material containing SiN and a film formed of a material containing SiO₂.

As shown in FIG. 5, the element insulating layer 40 includes the substrate side insulating layer 50 provided on the substrate 30 and the front surface side insulating layer 60 stacked on the substrate side insulating layer 50. The substrate side insulating layer 50 is, for example, an insulating layer for improving a dielectric breakdown voltage of the first chip 14. The substrate side insulating layer 50 is an insulating layer that includes the element back surface 42 of the element insulating layer 40. Therefore, the substrate side insulating layer 50 is in contact with the substrate 30.

The substrate side insulating layer 50 includes a plurality of etching stopper films 51 and a plurality of interlayer insulating films 52 formed on the plurality of etching stopper films 51. The etching stopper films 51 and the interlayer insulating films 52 are alternately stacked one by one in the Z direction. Here, the etching stopper film 51 corresponds to a “first insulating film,” and the interlayer insulating film 52 corresponds to a “second insulating film.”

The etching stopper film 51 is formed of a material containing SiN (silicon nitride), SiC, SiCN (nitrogen-doped silicon carbide), or the like. In the first embodiment, the etching stopper film 51 is formed of a material containing SiN.

The interlayer insulating film 52 is an insulating film that relieves a stress of the etching stopper film 51. The interlayer insulating film 52 is an oxide film formed of a material containing, for example, SiO₂ (silicon oxide). The interlayer insulating film 52 is thicker than the etching stopper film 51. The etching stopper film 51 has a thickness of 50 nm or more and less than 1,000 nm. The interlayer insulating film 52 has a thickness of 500 nm or more and 5,000 nm or less. In the first embodiment, the etching stopper film 51 has a thickness of about 300 nm, and the interlayer insulating film 52 has a thickness of about 2,000 nm. From the viewpoint of ease of viewing the figure, a ratio between the thickness of the etching stopper film 51 and the thickness of the interlayer insulating film 52 in the figure is different from a ratio between an actual thickness of the etching stopper film 51 and an actual thickness of the interlayer insulating film 52.

The front surface side insulating layer 60 is in contact with the uppermost interlayer insulating film 52 of the substrate side insulating layer 50. A thickness of the front surface side insulating layer 60 is thicker than a total thickness of one etching stopper film 51 and one interlayer insulating film 52. The front surface side insulating layer 60 is formed of a material containing, for example, SiO₂ (silicon oxide).

The semiconductor resistance layers 20 are provided in the element insulating layer 40. In the first embodiment, the semiconductor resistance layers 20 are provided on the substrate side insulating layer 50. The semiconductor resistance layers 20 are covered with the front surface side insulating layer 60. Therefore, it can be said that the semiconductor resistance layers 20 are embedded in the element insulating layer 40. As described above, it can be said that the first chip 14 includes the semiconductor resistance layers 20 provided on the substrate side insulating layer 50 and the front surface side insulating layer 60 covering the semiconductor resistance layers 20.

### [Configuration of Semiconductor Resistance Layer]

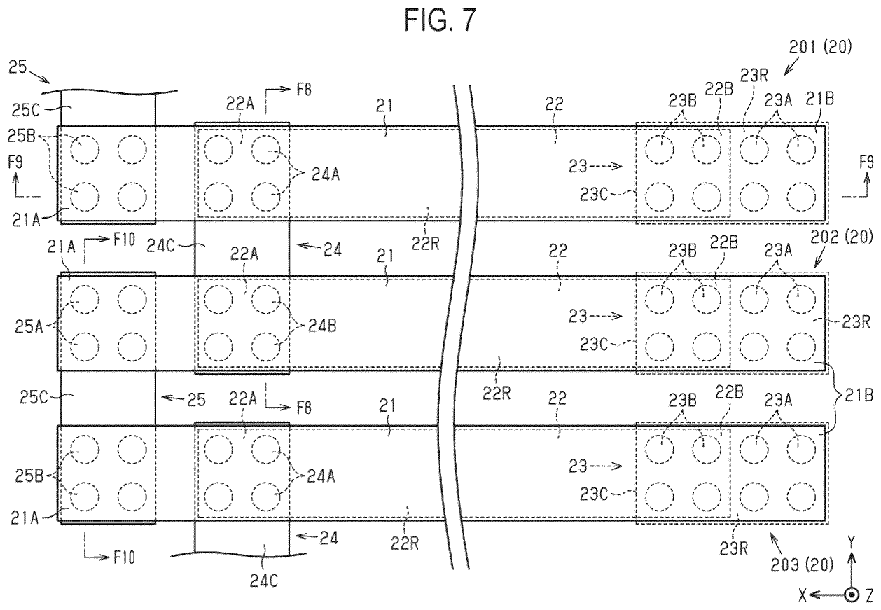

A configuration of the semiconductor resistance layer 20 will be described with reference to FIGS. 6 and 7. FIG. 6 shows a cross-sectional structure of the semiconductor resistance layer 20A electrically connected to the terminal P1. FIG. 7 shows a planar structure of a portion of the plurality of semiconductor resistance layers 20. In the following description of the semiconductor resistance layer 20, the semiconductor resistance layer 20A is used when it is related to the wiring layer 91, and the semiconductor resistance layer 20 is used when it is not related to the wiring layer 91. Further, in FIG. 7, for ease of understanding the figure, contour lines of components that overlap with each other in a plan view are shown shifted from each other.

As shown in FIGS. 6 and 7, each semiconductor resistance layer 20 includes a front surface side resistance layer 21 extending in the X direction, a substrate side resistance layer 22 arranged closer to the substrate 30 (see FIG. 5) than the front surface side resistance layer 21 in the Z direction, and an internal connector 23 that electrically connects the front surface side resistance layer 21 and the substrate side resistance layer 22 in series. It can be said that the substrate side resistance layer 22 is arranged closer to the substrate side insulating layer 50 than the front surface side resistance layer 21 in the Z direction.

Here, in the present disclosure, the X direction corresponds to a “first direction,” the Z direction corresponds to a “substrate thickness direction,” and the Y direction corresponds to a “second direction.” Therefore, the first direction is a direction perpendicular to the thickness direction of the substrate. The second direction is a direction perpendicular to both the first direction and the substrate thickness direction.

The front surface side resistance layer 21 is formed in a band shape with a length direction being the X direction and with a width direction being the Y direction. A thickness of the front surface side resistance layer 21 is thinner than a width dimension of the front surface side resistance layer 21 (a size of the front surface side resistance layer 21 in the Y direction). The thickness of the front surface side resistance layer 21 is, for example, 1 nm or more and 100 nm or less. In one example, the thickness of the front surface side resistance layer 21 is about 2.5 nm. The front surface side resistance layer 21 is formed of a material containing, for example, CrSi (chromium silicon). The front surface side resistance layer 21 may have a thickness thinner than the interlayer insulating film 52. The front surface side resistance layer 21 may have a thickness thinner than the etching stopper film 51.

The front surface side resistance layer 21 includes a first end portion 21A and a second end portion 21B as both end portions in the X direction. In the front surface side resistance layer 21 of the semiconductor resistance layer 20A shown in FIG. 6, the first end portion 21A constitutes, for example, an end portion, which is closer to the terminal P1 in the X direction, of both end portions of the front surface side resistance layer 21. The second end portion 21B constitutes, for example, an end portion, which is farther from the terminal P1 in the X direction, of both end portions of the front surface side resistance layer 21.

As shown in FIG. 6, the substrate side resistance layer 22 is arranged to be spaced apart from the front surface side resistance layer 21 in the Z direction. Therefore, a portion of the front surface side insulating layer 60 is interposed between the substrate side resistance layer 22 and the front surface side resistance layer 21. The substrate side resistance layer 22 is arranged to be spaced apart from the substrate side insulating layer 50 in the Z direction and closer to the element front surface 41 (closer to the front surface side resistance layer 21). As described above, it can be said that both the substrate side resistance layer 22 and the front surface side resistance layer 21 are embedded in the front surface side insulating layer 60. In other words, it can be said that the semiconductor resistance layer 20 is embedded in the front surface side insulating layer 60.

The substrate side resistance layer 22 extends in the X direction. The substrate side resistance layer 22 is formed in a band shape with a length direction being the X direction and with a width direction being the Y direction. In one example, a thickness of the substrate side resistance layer 22 is equal to the thickness of the front surface side resistance layer 21. Here, when a difference between the thickness of the substrate side resistance layer 22 and the thickness of the front surface side resistance layer 21 is within, for example, 10% of the thickness of the substrate side resistance layer 22, it can be said that the thickness of the substrate side resistance layer 22 is equal to the thickness of the front surface side resistance layer 21. In the first embodiment, a length dimension of the substrate side resistance layer 22 (a length of the substrate side resistance layer 22 in the X direction) is shorter than the length dimension of the front surface side resistance layer 21 (the length of the front surface side resistance layer 21 in the X direction). In other words, the length dimension of the front surface side resistance layer 21 is longer than the length dimension of the substrate side resistance layer 22. In a plan view, a width dimension of the substrate side resistance layer 22 (a length of the substrate side resistance layer 22 in the Y direction) is equal to the width dimension of the front surface side resistance layer 21 (the length of the front surface side resistance layer 21 in the Y direction). Here, when a difference between the width dimension of the substrate side resistance layer 22 and the width dimension of the front surface side resistance layer 21 is within, for example, 10% of the width dimension of the substrate side resistance layer 22, it can be said that the width dimension of the substrate side resistance layer 22 is equal to the width dimension of the front surface side resistance layer 21. The substrate side resistance layer 22 is formed of a material containing, for example, CrSi. It can also be said that the substrate side resistance layer 22 is formed of the same material as the front surface side resistance layer 21.

The substrate side resistance layer 22 includes a first end portion 22A and a second end portion 22B as both end portions in the X direction. In the substrate side resistance layer 22 of the semiconductor resistance layer 20A shown in FIG. 6, the first end portion 22A constitutes, for example, an end portion, which is closer to the terminal P1 in the X direction, of both end portions of the substrate side resistance layer 22. The second end portion 22B constitutes, for example, an end portion, which is farther from the terminal P1 in the X direction, of both end portions of the substrate side resistance layer 22.

As shown in FIG. 7, the substrate side resistance layer 22 is arranged at a position overlapping with the front surface side resistance layer 21 in a plan view. That is, the substrate side resistance layer 22 includes an overlap region 22R that overlaps with the front surface side resistance layer 21 in a plan view.

The first end portion 22A of the substrate side resistance layer 22 is located at a position shifted from the first end portion 21A of the front surface side resistance layer 21 in the X direction. More specifically, the first end portion 22A is located closer to the second end portion 21B than the first end portion 21A in the X direction. The second end portion 22B of the substrate side resistance layer 22 is located at a position shifted from the second end portion 21B of the front surface side resistance layer 21 in the X direction. More specifically, the second end portion 22B is located closer to the first end portion 21A than the second end portion 21B in the X direction. Therefore, in the first embodiment, the overlap region 22R is formed over the entire substrate side resistance layer 22 in the X direction. Further, in the first embodiment, the overlap region 22R is formed over the entire substrate side resistance layer 22 in the Y direction. As described above, in the first embodiment, the substrate side resistance layer 22 does not have a portion protruding from the front surface side resistance layer 21 in a plan view.

As shown in FIG. 6, the internal connector 23 electrically connects the second end portion 21B of the front surface side resistance layer 21 and the second end portion 22B of the substrate side resistance layer 22. The internal connector 23 includes first internal via 23A, a second internal via 23B, and an internal wiring layer 23C.

The first internal via 23A is connected to the front surface side resistance layer 21. In the Z direction, the first internal via 23A is arranged at a position closer to the substrate side resistance layer 22 than the front surface side resistance layer 21. The first internal via 23A is arranged at a position overlapping with the second end portion 21B of the front surface side resistance layer 21 in a plan view. That is, the first internal via 23A is connected to the second end portion 21B of the front surface side resistance layer 21. The first internal via 23A extends in the Z direction. In the illustrated example, the number of first internal vias 23A is four, but is not limited thereto. The number of first internal vias 23A can be changed arbitrarily.

The second internal via 23B is provided at a different position from the first internal via 23A in the X direction. The second internal via 23B is connected to the substrate side resistance layer 22. In the Z direction, the second internal via 23B is arranged at a position closer to the substrate 30 (see FIG. 5) than the substrate side resistance layer 22. The second internal via 23B is arranged at a position overlapping with the second end portion 22B of the substrate side resistance layer 22 in a plan view. That is, the second internal via 23B is connected to the second end portion 22B of the substrate side resistance layer 22. The second internal via 23B extends in the Z direction. A length of the second internal via 23B in the Z direction is shorter than a length of the first internal via 23A in the Z direction. In the illustrated example, the number of second internal vias 23B is four, but is not limited thereto. The number of second internal vias 23B can be changed arbitrarily.

The first internal via 23A and the second internal via 23B are formed of a material containing at least one of Ti, TiN, Ta, TaN, Au, Ag, Cu, Al, or W. In one example, the first internal via 23A and the second internal via 23B are formed of a material containing W. As described above, the first internal via 23A may be formed of the same material as the second internal via 23B.

The internal wiring layer 23C is arranged at a different position from both the front surface side resistance layer 21 and the substrate side resistance layer 22 in the Z direction. In the first embodiment, the internal wiring layer 23C is arranged at a position closer to the substrate 30 than both the front surface side resistance layer 21 and the substrate side resistance layer 22 in the Z direction.

As shown in FIG. 7, the internal wiring layer 23C extends in the X direction. The internal wiring layer 23C is formed in a band shape with a length direction being the X direction and with a width direction being the Y direction. A length dimension of the internal wiring layer 23C (a size of the internal wiring layer 23C in the X direction) is shorter than the length dimension of the substrate side resistance layer 22. As shown in FIG. 6, the internal wiring layer 23C is thicker than the front surface side resistance layer 21 and the substrate side resistance layer 22.

As shown in FIG. 7, the internal wiring layer 23C is arranged at a position overlapping with the front surface side resistance layer 21 and the substrate side resistance layer 22 in a plan view. That is, the internal wiring layer 23C includes an overlap region 23R that overlaps with the front surface side resistance layer 21 and the substrate side resistance layer 22 in a plan view.

As shown in FIGS. 6 and 7, the internal wiring layer 23C is arranged at a position overlapping with both the second end portion 22B of the substrate side resistance layer 22 and the second end portion 21B of the front surface side resistance layer 21 in a plan view. The overlap region 23R includes a region that overlaps with the second end portion 22B of the substrate side resistance layer 22 in a plan view, and a region that protrudes from the second end portion 22B in the X direction and overlaps with the second end portion 21B of the front surface side resistance layer 21 in a plan view. Therefore, in the first embodiment, the overlap region 23R is formed over the entire internal wiring layer 23C in the X direction. Further, in the first embodiment, the overlap region 23R is formed over the entire internal wiring layer 23C in the Y direction. As described above, in the first embodiment, the internal wiring layer 23C does not have a portion that protrudes from the front surface side resistance layer 21 in a plan view.

The internal wiring layer 23C is arranged to be spaced apart from the substrate side resistance layer 22 in the Z direction. Therefore, a portion of the front surface side insulating layer 60 is interposed between the internal wiring layer 23C and the substrate side resistance layer 22 in the Z direction and between the internal wiring layer 23C and the front surface side resistance layer 21 in the Z direction.

The internal wiring layer 23C is connected to both the first internal via 23A and the second internal via 23B. Therefore, the first internal via 23A penetrates the front surface side insulating layer 60 in the Z direction between the internal wiring layer 23C and the front surface side resistance layer 21 in the Z direction. The second internal via 23B penetrates the front surface side insulating layer 60 in the Z direction between the internal wiring layer 23C and the substrate side resistance layer 22 in the Z direction. The internal wiring layer 23C is formed of a material containing at least one of Ti, TiN, Ta, TaN, Au, Ag, Cu, Al, or W. In one example, the internal wiring layer 23C is formed of a material containing Al.

As shown in FIG. 6, the semiconductor resistance layer 20A is electrically connected to the terminal P1 by a terminal connector 80. The terminal connector 80 is electrically connected to the front surface side resistance layer 21 of the semiconductor resistance layer 20A. The terminal connector 80 is located at a position shifted from the substrate side resistance layer 22 in the X direction. On the other hand, the terminal connector 80 is arranged at a position overlapping with the front surface side resistance layer 21 in a plan view. The terminal connector 80 has a portion that protrudes from the front surface side resistance layer 21 in the X direction in a plan view.

The terminal connector 80 includes a first terminal via 81, a second terminal via 82, and the wiring layer 91. Each of the first terminal via 81, the second terminal via 82, and the wiring layer 91 is embedded in the front surface side insulating layer 60.

The first terminal via 81 is connected to the first end portion 21A of the front surface side resistance layer 21. The first terminal via 81 is arranged at a position closer to the substrate side resistance layer 22 than the front surface side resistance layer 21 in the Z direction. The first terminal via 81 extends in the Z direction. A length of the first terminal via 81 in the Z direction is equal to the length of the first internal via 23A in the Z direction. Here, when a difference between the length of the first terminal via 81 in the Z direction and the length of the first internal via 23A in the Z direction is within, for example, 10% of the length of the first internal via 23A in the Z direction, it can be said that the length of the first terminal via 81 in the Z direction is equal to the length of the first internal via 23A in the Z direction.

The second terminal via 82 is connected to the terminal P1. The second terminal via 82 is arranged at a different position from the front surface side resistance layer 21 (the semiconductor resistance layer 20A) in the X direction. The second terminal via 82 extends in the Z direction. A length of the second terminal via 82 in the Z direction is longer than the length of the first terminal via 81 in the Z direction.

The wiring layer 91 is arranged at a position overlapping with both the front surface side resistance layer 21 and the terminal P1 in a plan view. The wiring layer 91 includes a portion protruding from the front surface side resistance layer 21 in the X direction. The wiring layer 91 is arranged to be spaced apart from the front surface side resistance layer 21 in the Z direction. Therefore, a portion of the front surface side insulating layer 60 is interposed between the wiring layer 91 and the front surface side resistance layer 21 in the Z direction and between the wiring layer 91 and the terminal P1 in the Z direction. In one example, the wiring layer 91 is arranged at the same position as the internal wiring layer 23C in the Z direction. Further, the position of the wiring layer 91 in the Z direction can be changed arbitrarily. In one example, the wiring layer 91 may be arranged closer to the front surface side resistance layer 21 than the internal wiring layer 23C in the Z direction.

The wiring layer 91 is connected to both the first terminal via 81 and the second terminal via 82. Therefore, the first terminal via 81 penetrates the front surface side insulating layer 60 in the Z direction between the wiring layer 91 and the front surface side resistance layer 21 in the Z direction. The second terminal via 82 penetrates the front surface side insulating layer 60 in the Z direction between the wiring layer 91 and the terminal P1 in the Z direction.

Each of the first terminal via 81, the second terminal via 82, and the wiring layer 91 is formed of a material containing at least one of Ti, TiN, Ta, TaN, Au, Ag, Cu, Al, or W. In one example, the first terminal via 81 and the second terminal via 82 are formed of a material containing W. That is, the first terminal via 81 and the second terminal via 82 may be formed of the same material. In one example, the wiring layer 91 is formed of a material containing Al. That is, the wiring layer 91 may be formed of a material different from that of the first terminal via 81 and the second terminal via 82. The wiring layer 91 may be formed of the same material as the internal wiring layer 23C.

Although not shown, connection configurations of the semiconductor resistance layers 20B to 20F, the wiring layers 92 to 95, and the terminals P2 to P5 are generally the same as the configurations of the semiconductor resistance layer 20A, the wiring layer 91, and the terminal P1 described above. Therefore, explanation thereof will be omitted.

[Connection Configuration between Semiconductor Resistance Layers]

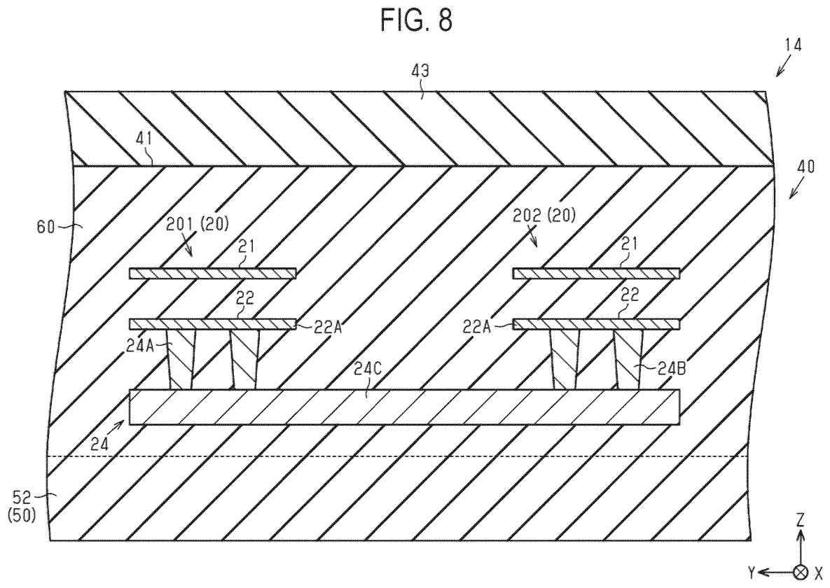

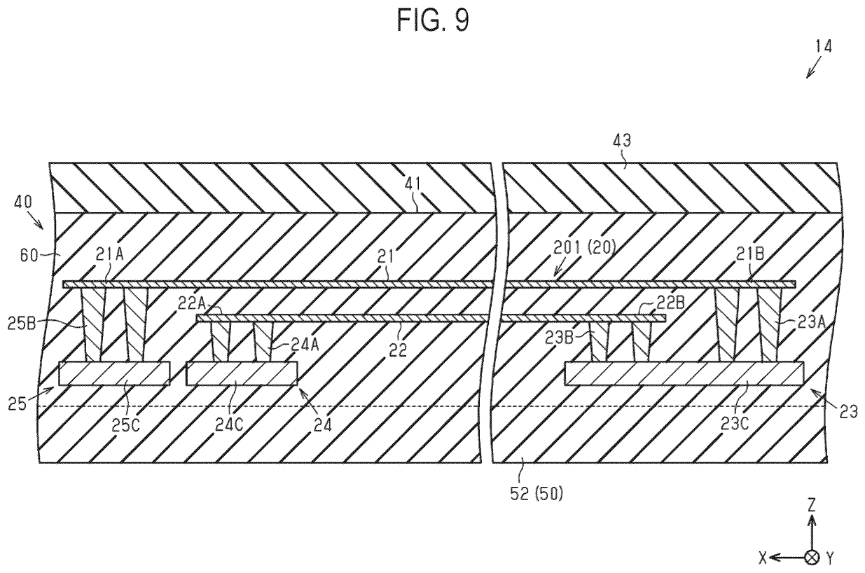

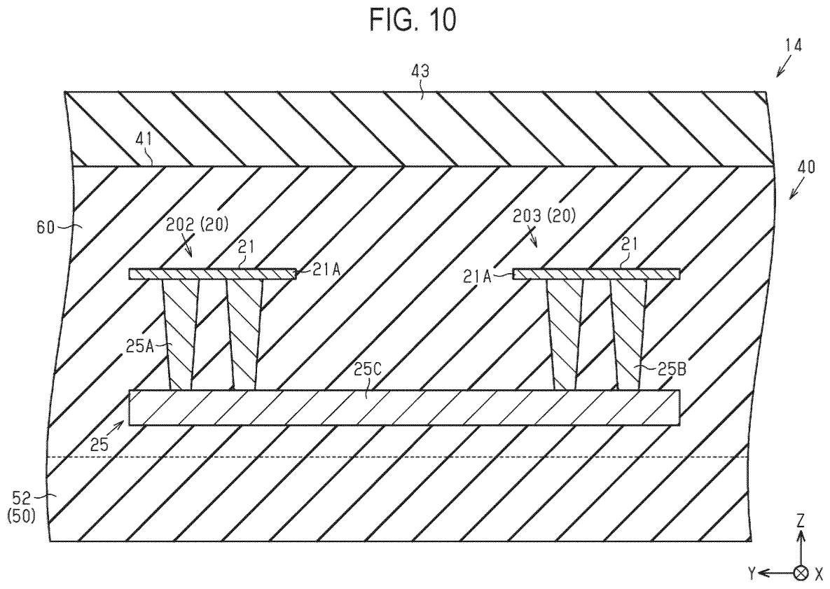

A connection configuration between semiconductor resistance layers 20 adjacent to each other in the Y direction will be described with reference to FIGS. 7 to 10. FIG. 8 shows a cross-sectional structure of the first chip 14, which is taken along line F8-F8 of FIG. 7. FIG. 9 shows a cross-sectional structure of the first chip 14, which is taken along line F9-F9 of FIG. 7. FIG. 10 shows a cross-sectional structure of the first chip 14, which is taken along line F10-F10 of FIG. 7. Further, in FIGS. 8 to 10, a portion of the substrate side insulating layer 50 and the substrate 30 are omitted.

In the following description, for the sake of convenience, three semiconductor resistance layers 20 adjacent in the Y direction are referred to as a “first semiconductor resistance layer 201,” a “second semiconductor resistance layer 202,” and a “third semiconductor resistance layer 203,” respectively, as shown in FIG. 7. That is, it can be said that the semiconductor resistance layers 20 include the first semiconductor resistance layer 201, the second semiconductor resistance layer 202, and the third semiconductor resistance layer 203. The second semiconductor resistance layer 202 is arranged between the first semiconductor resistance layer 201 and the third semiconductor resistance layer 203 in the Y direction. Further, common constituent elements of each of the semiconductor resistance layers 201 to 203 will be described using the same reference numerals.

As shown in FIGS. 7 and 8, the first chip 14 includes a first external connector 24 that electrically connects the substrate side resistance layer 22 of the first semiconductor resistance layer 201 and the substrate side resistance layer 22 of the second semiconductor resistance layer 202, which are adjacent to each other in the Y direction. The first semiconductor resistance layer 201 and the second semiconductor resistance layer 202 are electrically connected in series by the first external connector 24.

The first external connector 24 is arranged closer to the first end portions 21A and 22A than the center of the semiconductor resistance layer 20 in the X direction. The first external connector 24 connects the first end portion 22A of the substrate side resistance layer 22 of the first semiconductor resistance layer 201 and the first end portion 22A of the substrate side resistance layer 22 of the second semiconductor resistance layer 202. The first external connector 24 includes a first substrate side via 24A, a second substrate side via 24B, and a first external wiring layer 24C.

The first substrate side via 24A is connected to the substrate side resistance layer 22 of the first semiconductor resistance layer 201. The first substrate side via 24A is arranged at a position closer to the substrate 30 (see FIG. 5) than the substrate side resistance layer 22 in the Z direction. The first substrate side via 24A is arranged at a position overlapping with the first end portion 22A of the substrate side resistance layer 22 in a plan view. That is, the first substrate side via 24A is connected to the first end portion 22A of the substrate side resistance layer 22 of the first semiconductor resistance layer 201. The first substrate side via 24A extends in the Z direction. In the examples of FIGS. 7 and 8, the number of first substrate side vias 24A is four, but is not limited thereto. The number of first substrate side vias 24A can be changed arbitrarily.

The second substrate side via 24B is connected to the substrate side resistance layer 22 of the second semiconductor resistance layer 202. The second substrate side via 24B is arranged at a position closer to the substrate 30 than the substrate side resistance layer 22 in the Z direction. The second substrate side via 24B is arranged at the same position as the first substrate side via 24A in the Z direction.

The second substrate side via 24B is arranged at a position overlapping with the first end portion 22A of the substrate side resistance layer 22 in a plan view. That is, the second substrate side via 24B is connected to the first end portion 22A of the substrate side resistance layer 22 of the second semiconductor resistance layer 202. As described above, the second substrate side via 24B is arranged at the same position as the first substrate side via 24A in the X direction. The second substrate side via 24B extends in the Z direction. A length of the second substrate side via 24B in the Z direction is equal to a length of the first substrate side via 24A in the Z direction. Here, when a difference between the length of the second substrate side via 24B in the Z direction and the length of the first substrate side via 24A in the Z direction is within, for example, 10% of the length of the first substrate side via 24A in the Z direction, it can be said that the length of the second substrate side via 24B in the Z direction is equal to the length of the first substrate side via 24A in the Z direction. In the example of FIG. 8, the number of second substrate side vias 24B is four, but is not limited thereto. The number of second substrate side vias 24B can be changed arbitrarily.

The first substrate side via 24A and the second substrate side via 24B are formed of a material containing at least one of Ti, TiN, Ta, TaN, Au, Ag, Cu, Al, or W. In one example, the first substrate side via 24A and the second substrate side via 24B are formed of a material containing W. As described above, the first substrate side via 24A may be formed of the same material as the second substrate side via 24B. Further, the first substrate side via 24A may be formed of the same material as the first internal via 23A and the second internal via 23B (both see FIG. 6).

The first external wiring layer 24C extends in the Y direction. The first external wiring layer 24C is formed in a band shape with a length direction being the Y direction and with a width direction being the X direction. The first external wiring layer 24C extends so as to overlap with both the substrate side resistance layer 22 of the first semiconductor resistance layer 201 and the substrate side resistance layer 22 of the second semiconductor resistance layer 202 in a plan view. The first external wiring layer 24C overlaps with both the first end portion 22A of the substrate side resistance layer 22 of the first semiconductor resistance layer 201 and the first end portion 22A of the substrate side resistance layer 22 of the second semiconductor resistance layer 202. In the first embodiment, the first external wiring layer 24C is arranged closer to the substrate 30 than both the substrate side resistance layer 22 of the first semiconductor resistance layer 201 and the substrate side resistance layer 22 of the second semiconductor resistance layer 202. As shown in FIG. 8, since the first external wiring layer 24C is arranged to be spaced apart from the substrate side resistance layer 22 in the Z direction, a portion of the front surface side insulating layer 60 is interposed between the first external wiring layer 24C and the substrate side resistance layer 22 of the first semiconductor resistance layer 201 and between the first external wiring layer 24C and the substrate side resistance layer 22 of the second semiconductor resistance layer 202 in the Z direction.

As shown in FIG. 9, the first external wiring layer 24C is arranged at the same position as the internal wiring layer 23C of the internal connector 23 in the Z direction. A thickness of the first external wiring layer 24C is thicker than both the thickness of the front surface side resistance layer 21 and the thickness of the substrate side resistance layer 22. In one example, the thickness of the first external wiring layer 24C is equal to the thickness of the internal wiring layer 23C. Here, when a difference between the thickness of the first external wiring layer 24C and the thickness of the internal wiring layer 23C is within, for example, 10% of the thickness of the first external wiring layer 24C, it can be said that the thickness of the first external wiring layer 24C is equal to the thickness of the internal wiring layer 23C.

The first external wiring layer 24C is connected to both the first substrate side via 24A and the second substrate side via 24B. Therefore, the first substrate side via 24A penetrates the front surface side insulating layer 60 in the Z direction between the first external wiring layer 24C and the substrate side resistance layer 22 of the first semiconductor resistance layer 201 in the Z direction. The second substrate side via 24B penetrates the front surface side insulating layer 60 in the Z direction between the first external wiring layer 24C and the substrate side resistance layer 22 of the second semiconductor resistance layer 202 in the Z direction. The first external wiring layer 24C is formed of a material containing at least one of Ti, TiN, Ta, TaN, Au, Ag, Cu, Al, or W. In one example, the first external wiring layer 24C is formed of a material containing Al. Further, in one example, the first external wiring layer 24C is formed of the same material as the internal wiring layer 23C.

As shown in FIGS. 7 and 10, the first chip 14 includes a second external connector 25 that electrically connects the front surface side resistance layer 21 of the second semiconductor resistance layer 202 and the front surface side resistance layer 21 of the third semiconductor resistance layer 203, which are adjacent to each other in the Y direction. The second semiconductor resistance layer 202 and the third semiconductor resistance layer 203 are electrically connected in series by the second external connector 25.

The second external connector 25 is arranged closer to the first end portions 21A and 22A than the center of the semiconductor resistance layer 20 in the X direction. The second external connector 25 connects the first end portion 21A of the front surface side resistance layer 21 of the second semiconductor resistance layer 202 and the first end portion 21A of the front surface side resistance layer 21 of the third semiconductor resistance layer 203. Therefore, as shown in FIG. 9, the second external connector 25 is arranged at a different position from the first external connector 24 in the X direction. Further, as shown in FIG. 7, the second external connector 25 is located to be shifted from the first external connector 24 in the Y direction. As shown in FIG. 10, the second external connector 25 includes a first front surface side via 25A, a second front surface side via 25B, and a second external wiring layer 25C.

The first front surface side via 25A is connected to the front surface side resistance layer 21 of the second semiconductor resistance layer 202. As shown in FIG. 9, the first front surface side via 25A is arranged at a position closer to the substrate side resistance layer 22 than the front surface side resistance layer 21 in the Z direction. As shown in FIG. 10, the first front surface side via 25A is arranged at a position overlapping with the first end portion 21A of the front surface side resistance layer 21 of the second semiconductor resistance layer 202 in a plan view. That is, the first front surface side via 25A is connected to the first end portion 21A of the front surface side resistance layer 21 of the second semiconductor resistance layer 202. The first front surface side via 25A extends in the Z direction. A length of the first front surface side via 25A in the Z direction is longer than the length of the first substrate side via 24A in the Z direction. In the examples shown in FIGS. 7 and 10, the number of first front surface side vias 25A is four, but is not limited thereto. The number of first front surface side vias 25A can be changed arbitrarily.

The second front surface side via 25B is connected to the front surface side resistance layer 21 of the third semiconductor resistance layer 203. As shown in FIG. 9, the second front surface side via 25B is arranged at a position closer to the substrate side resistance layer 22 than the front surface side resistance layer 21 in the Z direction. As shown in FIG. 10, the second front surface side via 25B is arranged at a position overlapping with the first end portion 21A of the front surface side resistance layer 21 of the third semiconductor resistance layer 203 in a plan view. That is, the second front surface side via 25B is connected to the first end portion 21A of the front surface side resistance layer 21 of the third semiconductor resistance layer 203. The second front surface side via 25B extends in the Z direction. A length of the second front surface side via 25B in the Z direction is equal to the length of the first front surface side via 25A in the Z direction. Here, when a difference between the length of the second front surface side via 25B in the Z direction and the length of the first front surface side via 25A in the Z direction is within, for example, 10% of the length of the first front surface side via 25A in the Z direction, it can be said that the length of the second front surface side via 25B in the Z direction is equal to the length of the first front surface side via 25A in the Z direction. In the examples shown in FIGS. 7 and 10, the number of second front surface side vias 25B is four, but is not limited thereto. The number of second front surface side vias 25B can be changed arbitrarily.

The first front surface side via 25A and the second front surface side via 25B are formed of a material containing at least one of Ti, TiN, Ta, TaN, Au, Ag, Cu, Al, or W. In one example, the first front surface side via 25A and the second front surface side via 25B are formed of a material containing W. As described above, the first front surface side via 25A may be formed of the same material as the second front surface side via 25B. Further, the first front surface side via 25A may be formed of the same material as the first substrate side via 24A and the second substrate side via 24B (see FIG. 9).

As shown in FIG. 7, the second external wiring layer 25C extends in the Y direction. The second external wiring layer 25C is formed in a band shape with a length direction being the Y direction and with a width direction being the X direction. The second external wiring layer 25C extends so as to overlap with both the front surface side resistance layer 21 of the second semiconductor resistance layer 202 and the front surface side resistance layer 21 of the third semiconductor resistance layer 203 in a plan view. The second external wiring layer 25C overlaps with both the first end portion 21A of the front surface side resistance layer 21 of the second semiconductor resistance layer 202 and the first end portion 21A of the front surface side resistance layer 21 of the third semiconductor resistance layer 203. In the first embodiment, the second external wiring layer 25C is arranged closer to the substrate 30 than both the front surface side resistance layer 21 of the second semiconductor resistance layer 202 and the front surface side resistance layer 21 of the third semiconductor resistance layer 203 (see FIG. 5). As shown in FIG. 10, since the second external wiring layer 25C is arranged to be spaced apart from the front surface side resistance layer 21 in the Z direction, a portion of the front surface side insulating layer 60 is interposed between the second external wiring layer 25C and the front surface side resistance layer 21 of the second semiconductor resistance layer 202 and between the second external wiring layer 25C and the front surface side resistance layer 21 of the third semiconductor resistance layer 203 in the Z direction.

As shown in FIG. 9, the second external wiring layer 25C is arranged at the same position as the first external wiring layer 24C in the Z direction. Therefore, the second external wiring layer 25C is arranged at the same position as the internal wiring layer 23C of the internal connector 23 in the Z direction. A thickness of the second external wiring layer 25C is thicker than both the thickness of the front surface side resistance layer 21 and the thickness of the substrate side resistance layer 22. In one example, the thickness of the second external wiring layer 25C is equal to the thickness of the first external wiring layer 24C. Here, when a difference between the thickness of the second external wiring layer 25C and the thickness of the first external wiring layer 24C is within, for example, 10% of the thickness of the first external wiring layer 24C, it can be said that the thickness of the second external wiring layer 25C is equal to the thickness of the first external wiring layer 24C.

As shown in FIG. 10, the second external wiring layer 25C is connected to both the first front surface side via 25A and the second front surface side via 25B. Therefore, the first front surface side via 25A penetrates the front surface side insulating layer 60 in the Z direction between the second external wiring layer 25C and the front surface side resistance layer 21 of the second semiconductor resistance layer 202. The second front surface side via 25B penetrates the front surface side insulating layer 60 in the Z direction between the second external wiring layer 25C and the front surface side resistance layer 21 of the third semiconductor resistance layer 203 in the Z direction. The second external wiring layer 25C is formed of a material containing at least one of Ti, TiN, Ta, TaN, Au, Ag, Cu, Al, or W. In one example, the second external wiring layer 25C is formed of a material containing Al. Further, in one example, the second external wiring layer 25C is formed of the same material as the first external wiring layer 24C.

As described above, the first semiconductor resistance layer 201, the second semiconductor resistance layer 202, and the third semiconductor resistance layer 203 are electrically connected to one another in series by the first external connector 24 and the second external connector 25. As shown in FIG. 7, the first external connector 24 connects the front surface side resistance layer 21 of the third semiconductor resistance layer 203 and the front surface side resistance layer 21 of a semiconductor resistance layer 20 (not shown), which is arranged on the opposite side to the second semiconductor resistance layer 202 with respect to the third semiconductor resistance layer 203. The second external connector 25 connects the substrate side resistance layer 22 of the first semiconductor resistance layer 201 and the front surface side resistance layer 21 of a semiconductor resistance layer 20 (not shown), which is arranged on the opposite side to the second semiconductor resistance layer 202 with respect to the first semiconductor resistance layer 201 (not shown). As a result, the semiconductor resistance layers 20 are electrically connected in series.

It can be said that the first chip 14 includes a plurality of first external connectors 24 and a plurality of second external connectors 25. The first external connectors 24 are arranged at the same position in the X direction and spaced apart from one another in the Y direction. The second external connectors 25 are arranged at the same position in the X direction and spaced apart from one another in the Y direction. The first external connectors 24 and the second external connectors 25 are located to be shifted by just one semiconductor resistance layer 20 in the Y direction.

### [Method of Manufacturing First Chip]

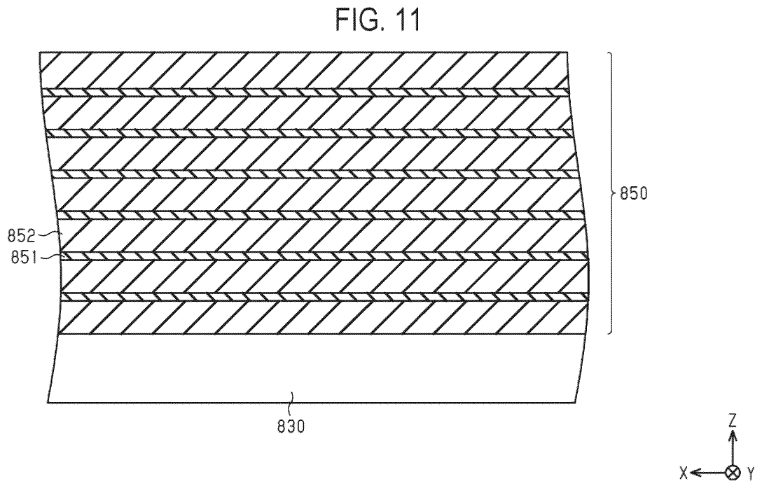

An example of a method of manufacturing the first chip 14 will be described with reference to FIGS. 11 to 18. FIGS. 11 to 18 show processes of manufacturing the first chip 14 and show cross-sectional structures of the constituent elements of the first chip 14.

The method of manufacturing the first chip 14 mainly includes a process of preparing a substrate 830, a process of forming a substrate side insulating layer 850 on the substrate 830, a process of forming a first front surface side insulating layer 861, a process of forming wiring layers, a process of forming a second front surface side insulating layer 862, a process of forming first vias, a process of forming the substrate side resistance layer 22, a process of forming a third front surface side insulating layer 863, a process of forming second vias, a process of forming the front surface side resistance layer 21, a process of forming a fourth front surface side insulating layer 864, a process of forming a passivation film 843, and a process of singulating. Further, the method of manufacturing the first chip 14 includes a process of forming third vias and a process of forming the terminals P1 to P5.

As shown in FIG. 11, in the process of preparing the substrate 830, the substrate 830, which is, for example, a Si substrate, is prepared. The substrate 830 is a component that constitutes the substrate 30, and is, for example, a semiconductor wafer. Here, the substrate 830 is configured to include a plurality of substrates 30.

Subsequently, the process of forming the substrate side insulating layer 850 on the substrate 830 is performed. In this process, the substrate side insulating layer 850 is formed on the substrate 830 by, for example, chemical vapor deposition (CVD). More specifically, the substrate side insulating layer 850 is formed by, for example, CVD such that an etching stopper film 851 and an interlayer insulating film 852 are alternately stacked. The substrate side insulating layer 850 is an insulating layer that constitutes the substrate side insulating layer 50. The etching stopper film 851 is an insulating film that constitutes the etching stopper film 51, and the interlayer insulating film 852 is an insulating film that constitutes the interlayer insulating film 52.

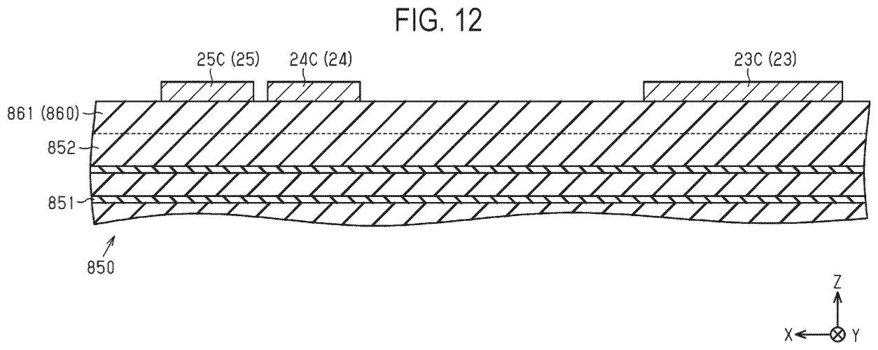

FIG. 12 shows the process of forming the first front surface side insulating layer 861 and the process of forming the wiring layers. From FIG. 12 onward, a portion of the substrate side insulating layer 850 and the substrate 830 are omitted for ease of understanding the figures.

As shown in FIG. 12, in the process of forming the first front surface side insulating layer 861, the first front surface side insulating layer 861 is formed on the substrate side insulating layer 850 by, for example, CVD. The first front surface side insulating layer 861 is formed of a material containing, for example, SiO₂. The first front surface side insulating layer 861 is an insulating layer that constitutes a portion of the front surface side insulating layer 60 between the substrate side insulating layer 50 and the internal wiring layer 23C of the internal connector 23, between the substrate side insulating layer 50 and the first external wiring layer 24C of the first external connector 24, and between the substrate side insulating layer 50 and the second external wiring layer 25C of the second external connector 25. As described above, the process of forming the first front surface side insulating layer 861 is a process of forming a portion of a front surface side insulating layer 860.

In FIG. 12, an interface between the first front surface side insulating layer 861 and the substrate side insulating layer 50 (the interlayer insulating film 852) that is in contact with the first front surface side insulating layer 861 is indicated by a two-dot chain line. However, actually, since the first front surface side insulating layer 861 and the interlayer insulating film 852 are formed of the same material, the interface between the first front surface side insulating layer 861 and the interlayer insulating film 852 may be not visible.

Subsequently, in the process of forming the wiring layers, a metal film (not shown), which is a material film of the internal wiring layer 23C of the internal connector 23, the first external wiring layer 24C of the first external connector 24, and the second external wiring layer 25C of the second external connector 25, is formed on the first front surface side insulating layer 861 by, for example, sputtering. As the metal film, one or more of, for example, Ti, TiN, Ta, TaN, Au, Ag, Cu, Al, and W are appropriately selected. Subsequently, the metal film is patterned by, for example, lithography and etching to form the internal wiring layer 23C, the first external wiring layer 24C, and the second external wiring layer 25C. That is, the internal wiring layer 23C, the first external wiring layer 24C, and the second external wiring layer 25C are formed simultaneously by patterning the metal film. Although not shown, the wiring layers 91 to 95 (see FIG. 3) are also formed simultaneously with the internal wiring layer 23C, the first external wiring layer 24C, and the second external wiring layer 25C by patterning the metal film.

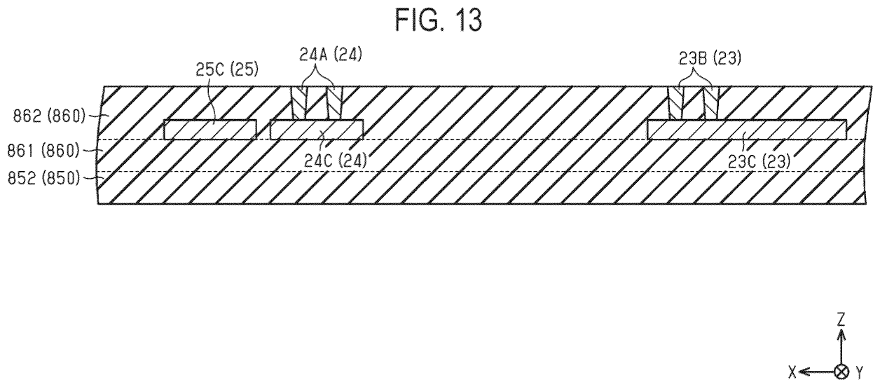

FIG. 13 shows the process of forming the second front surface side insulating layer 862 and the process of forming the first vias. In the process of forming the second front surface side insulating layer 862, the second front surface side insulating layer 862 is formed on the first front surface side insulating layer 861 so as to cover the internal wiring layer 23C, the first external wiring layer 24C, the second external wiring layer 25C, and the wiring layers 91 to 95 by, for example, CVD. The second front surface side insulating layer 862 is an insulating layer that constitutes a portion of the front surface side insulating layer 860. The second front surface side insulating layer 862 is formed of a material containing, for example, SiO₂. As described above, the process of forming the second front surface side insulating layer 862 is a process of forming a portion of the front surface side insulating layer 860.

Subsequently, in the process of forming the first vias, first, a plurality of via openings are formed by, for example, etching. These via openings penetrate the second front surface side insulating layer 862 in the Z direction and expose the internal wiring layer 23C and the first external wiring layer 24C. Subsequently, the via openings are filled with a metallic material by, for example, sputtering. As the metallic material, one or more of, for example, Ti, TiN, Ta, TaN, Au, Ag, Cu, Al, and W are appropriately selected. As a result, the second internal via 23B and the first substrate side via 24A are formed. Each of the second internal via 23B and the first substrate side via 24A is exposed from the second front surface side insulating layer 862 in the Z direction. Although not shown, the second substrate side via 24B is also formed in this process. The second substrate side via 24B is exposed from the second front surface side insulating layer 862 in the Z direction.

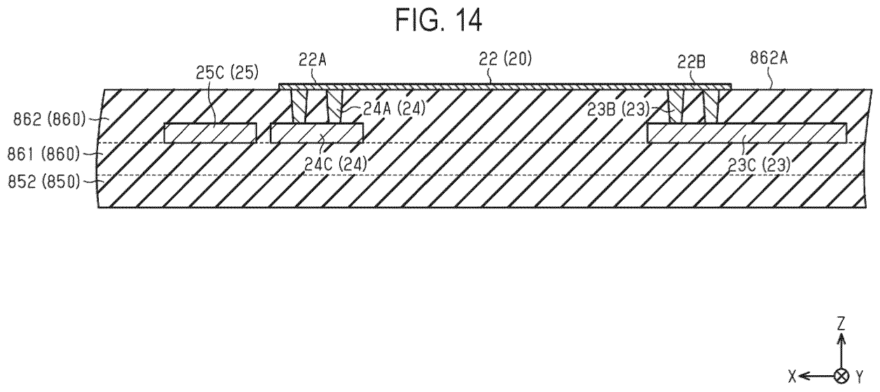

FIG. 14 shows the process of forming the substrate side resistance layer 22. In the process of forming the substrate side resistance layer 22, a resistive material film, which is a material film of the substrate side resistance layer 22, is formed on a surface 862A of the second front surface side insulating layer 862. The resistive material film is formed of a material containing, for example, CrSi. The resistive material film is formed, for example, over the entire surface 862A. Subsequently, the substrate side resistance layer 22 is formed by patterning the resistive material film by, for example, lithography and etching. Although not shown, in this process, a plurality of substrate side resistance layers 22 arranged to be spaced apart from one another in the Y direction is formed. Further, an upper end of the second internal via 23B and an upper end of the first substrate side via 24A are each connected to the substrate side resistance layer 22. Although not shown, the second substrate side via 24B is connected to a substrate side resistance layer 22 (not shown) adjacent to the substrate side resistance layer 22 of FIG. 14 in the Y direction. Through the above processes, the first external connector 24 is manufactured.

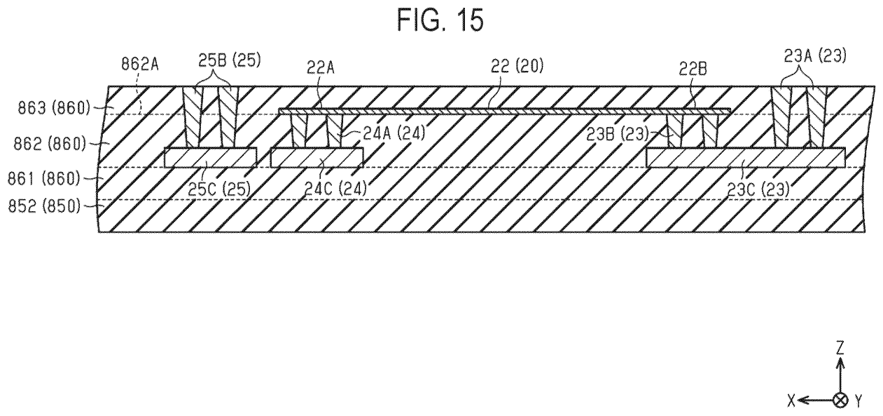

FIG. 15 shows the process of forming the third front surface side insulating layer 863 and the process of forming the second vias. In the process of forming the third front surface side insulating layer 863, the third front surface side insulating layer 863 is formed on the second front surface side insulating layer 862 by, for example, CVD so as to cover the substrate side resistance layer 22. The third front surface side insulating layer 863 is stacked on the surface 862A of the second front surface side insulating layer 862. The third front surface side insulating layer 863 is an insulating layer that constitutes a portion of the front surface side insulating layer 860. The third front surface side insulating layer 863 is formed of a material containing, for example, SiO₂.

Subsequently, in the process of forming the second vias, first, a plurality of via openings are formed by, for example, etching. These via openings penetrate the third front surface side insulating layer 863 and the second front surface side insulating layer 862 in the Z direction and expose the internal wiring layer 23C and the second external wiring layer 25C. Subsequently, the via openings are filled with a metallic material by, for example, sputtering. As the metallic material, one or more of, for example, Ti, TiN, Ta, TaN, Au, Ag, Cu, Al, and W are appropriately selected. As a result, the first internal via 23A and the first front surface side via 25A are formed. Each of the second internal via 23B and the first front surface side via 25A is exposed from the second front surface side insulating layer 862 in the Z direction. Although not shown, the second front surface side via 25B and the first terminal via 81 are also formed in this process. Each of the second front surface side via 25B and the first terminal via 81 is exposed from the second front surface side insulating layer 862 in the Z direction. Through the above processes, the internal connector 23 is manufactured.

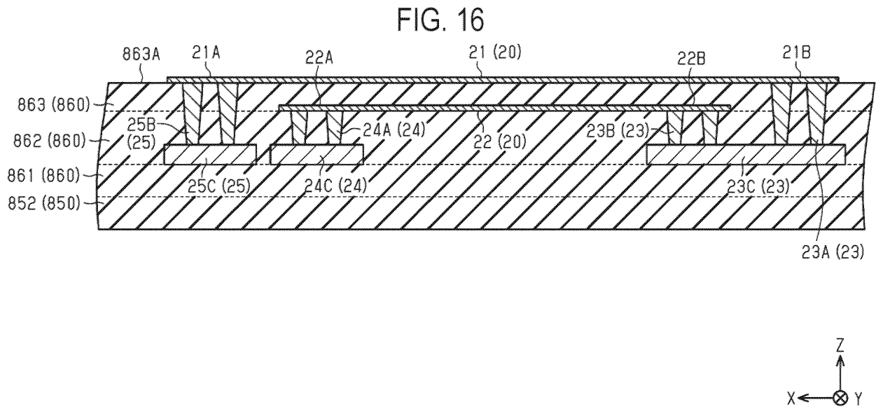

FIG. 16 shows the process of forming the front surface side resistance layer 21. In the process of forming the front surface side resistance layer 21, a resistive material film, which is a material film of the front surface side resistance layer 21, is formed on a surface 863A of the third front surface side insulating layer 863. The resistive material film is formed of a material containing, for example, CrSi. In one example, the resistive material film for forming the front surface side resistance layer 21 is formed of the same material as the resistive material film for forming the substrate side resistance layer 22. The resistive material film is formed, for example, over the entire surface 863A. Subsequently, the front surface side resistance layer 21 is formed by patterning the resistive material film by, for example, lithography and etching. Although not shown, in this process, a plurality of front surface side resistance layers 21 arranged to be spaced apart from one another in the Y direction is formed. In a plan view, each front surface side resistance layer 21 is formed at a position overlapping with each substrate side resistance layer 22.

Further, an upper end of the first internal via 23A and an upper end of the first front surface side via 25A are each connected to the front surface side resistance layer 21. Although not shown, the second front surface side via 25B is connected to a front surface side resistance layer 21 (not shown) adjacent to the front surface side resistance layer 21 of FIG. 16 in the Y direction. Although not shown, the first terminal via 81 is connected to a front surface side resistance layer 21 which is different from both the front surface side resistance layer 21 of FIG. 16 and the front surface side resistance layer 21 adjacent to the front surface side resistance layer 21 of FIG. 16 in the Y direction. Through the above processes, the second external connector 25 and the semiconductor resistance layer 20 are manufactured.

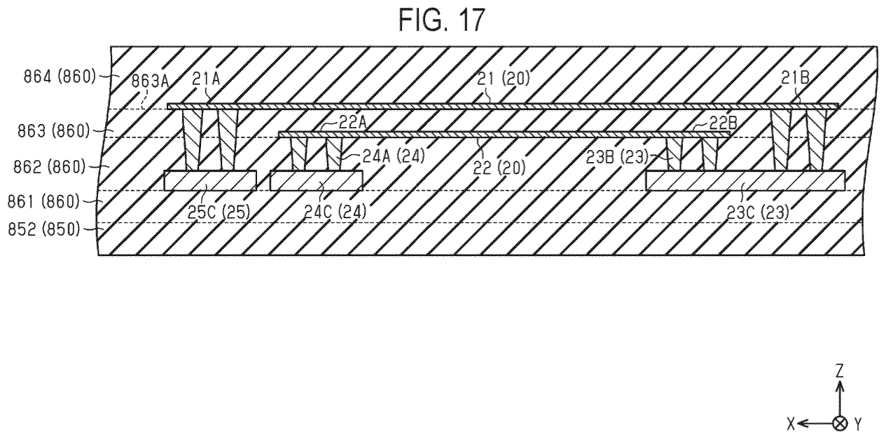

FIG. 17 shows the process of forming the fourth front surface side insulating layer 864. In the process of forming the fourth front surface side insulating layer 864, the fourth front surface side insulating layer 864 is formed on the third front surface side insulating layer 863 by, for example, CVD so as to cover the front surface side resistance layer 21. The fourth front surface side insulating layer 864 is stacked on the surface 863A of the third front surface side insulating layer 863. The fourth front surface side insulating layer 864 is an insulating layer that constitutes a portion of the front surface side insulating layer 860. The fourth front surface side insulating layer 864 is formed of a material containing, for example, SiO₂. Through the above processes, the front surface side insulating layer 860 is formed.

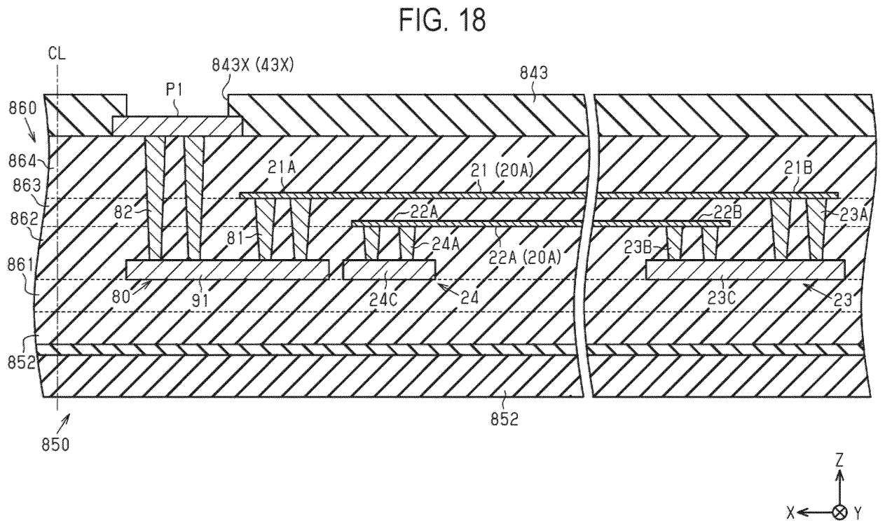

FIG. 18 shows the process of forming the third vias, the process of forming the terminals P1 to P5, the process of forming the passivation film 843, and the process of singulating. FIG. 18 shows a cross-sectional structure of the semiconductor resistance layer 20A and its surroundings.

In the process of forming the third vias, first, a plurality of via openings are formed by, for example, etching. These via openings penetrate the fourth front surface side insulating layer 864, the third front surface side insulating layer 863, and the second front surface side insulating layer 862 in the Z direction and expose the wiring layers 91 to 95 (see FIG. 3). The wiring layer 91 is shown in FIG. 18. Subsequently, the via openings are filled with a metallic material by, for example, sputtering. As the metallic material, one or more of, for example, Ti, TiN, Ta, TaN, Au, Ag, Cu, Al, and W are appropriately selected. As a result, the second terminal via 82 is formed. The second terminal via 82 is exposed from the front surface side insulating layer 860 in the Z direction.

Subsequently, in the process of forming the terminal P1, a metal film, which is a material film of the terminal P1, is formed on the fourth front surface side insulating layer 864 by, for example, sputtering. The metal film is in contact with the second terminal via 82. As the metal film, one or more of, for example, Ti, TiN, Ta, TaN, Au, Ag, Cu, Al, and W are appropriately selected. Subsequently, the terminal P1 is formed by patterning the metal film by lithography and etching. Although not shown, the terminals P2 to P5 are also formed in the same way. As described above, the terminals P1 to P5 are in contact with the second terminal via 82.

Subsequently, in the process of forming the passivation film 843, first, a passivation material film, which is a material film of the passivation film 843, is formed, for example, on the fourth front surface side insulating layer 864 and on the terminals P1 to P5. Subsequently, a portion of the passivation material film covering the terminals P1 to P5 is removed by, for example, etching. In other words, portions of the terminals P1 to P5 are exposed from the passivation material film. It can also be said that the passivation film 843 is formed with openings 843X that expose the terminals P1 to P5. As a result, the passivation film 843 is formed from the passivation material film. The passivation film 843 is a film that constitutes the passivation film 43, and is formed of a material containing, for example, SiN. Further, FIG. 18 shows an opening 843X that exposes the terminal P1. The opening 843X corresponds to the opening 43X.

Subsequently, in the process of singulating, the passivation film 843, the front surface side insulating layer 860, the substrate side insulating layer 850, and the substrate 830 (see FIG. 11) are cut along a cutting line CL in FIG. 18 using, for example, a dicing blade. As a result, the passivation film 43, the front surface side insulating layer 60, the substrate side insulating layer 50, and the substrate 30 are formed. Through the above processes, the first chip 14 is manufactured.

### [Operation]

An operation of the first embodiment will be described. In the first chip 14, a resistance value is mainly set according to a total length of the plurality of semiconductor resistance layers 20. In the first embodiment, the semiconductor resistance layer 20 includes the front surface side resistance layer 21 and the substrate side resistance layer 22, which are arranged at different positions in the Z direction, and the internal connector 23 that electrically connects the front surface side resistance layer 21 and the substrate side resistance layer 22 in series. As a result, the semiconductor resistance layer 20 has a structure in which the semiconductor resistance layer 20 is folded back. Therefore, as compared to a configuration in which the semiconductor resistance layer 20 includes only one of the front surface side resistance layer 21 and the substrate side resistance layer 22, the length dimension of the semiconductor resistance layer 20 in a plan view can be shortened. As a result, the first chip 14 can be made smaller in the X direction. Further, as compared to a configuration in which the semiconductor resistance layer 20 includes only one of the front surface side resistance layer 21 and the substrate side resistance layer 22, when the total length of the semiconductor resistance layer 20 is the same, the number of plural semiconductor resistance layers 20 can be reduced. As a result, the first chip 14 can be made smaller in the Y direction.

### [Effects]

According to the first embodiment, the following effects can be achieved.

(1-1) The first chip 14 includes the substrate 30, the element insulating layer 40 provided on the substrate 30, and the semiconductor resistance layer 20 provided on the element insulating layer 40. The semiconductor resistance layer 20 includes the front surface side resistance layer 21 extending in the first direction (the X direction) perpendicular to the thickness direction (the Z direction) of the substrate 30, the substrate side resistance layer 22 arranged closer to the substrate 30 than the front surface side resistance layer 21 in the Z direction, and the internal connector 23 that electrically connects the front surface side resistance layer 21 and the substrate side resistance layer 22 in series.

With this configuration, as compared to a configuration in which the semiconductor resistance layer 20 includes only one of the front surface side resistance layer 21 and the substrate side resistance layer 22, the length of the semiconductor resistance layer 20 in the length direction (the X direction) in a plan view can be shortened. As a result, the first chip 14 can be made smaller in the X direction.

(1-2) The substrate side resistance layer 22 includes the overlap region 22R that overlaps with the front surface side resistance layer 21 when viewed from the Z direction. With this configuration, the first chip 14 can be made smaller as compared to a configuration in which the substrate side resistance layer 22 does not include the overlap region 22R.

(1-3) The overlap region 22R is formed over the entire substrate side resistance layer 22 in the X direction. With this configuration, the first chip 14 can be made smaller in the X direction as compared to a case where the substrate side resistance layer 22 includes a portion shifted in the X direction with respect to the front surface side resistance layer 21.

(1-4) The overlap region 22R is formed over the entire substrate side resistance layer 22 in the Y direction. According to this configuration, the first chip 14 can be made smaller in the Y direction as compared to a case where the substrate side resistance layer 22 includes a portion shifted in the Y direction with respect to the front surface side resistance layer 21.

(1-5) The element insulating layer 40 includes the substrate side insulating layer 50 provided on the substrate 30, and the front surface side insulating layer 60 stacked on the substrate side insulating layer 50. The substrate side insulating layer 50 has a structure in which the plurality of etching stopper films 51 and the plurality of interlayer insulating films 52 that relieve a stress of the etching stopper films 51 are alternately stacked one by one. The semiconductor resistance layer 20 is embedded in the front surface side insulating layer 60.

With this configuration, by interposing the substrate side insulating layer 50 between the semiconductor resistance layer 20 embedded in the front surface side insulating layer 60 and the substrate 30, it is possible to increase a distance between the semiconductor resistance layer 20 and the substrate 30 in the Z direction. Therefore, the dielectric breakdown voltage of the first chip 14 can be improved.

Further, since the substrate side insulating layer 50 is configured such that the plurality of etching stopper films 51 and the plurality of interlayer insulating films 52 that relieve a stress of the etching stopper films 51 are alternately stacked one by one, even when the substrate side insulating layer 50 is made thicker, an increase in a warp amount of the first chip 14 can be suppressed.

(1-6) The internal wiring layer 23C of the internal connector 23, the first external wiring layer 24C of the first external connector 24, and the second external wiring layer 25C of the second external connector 25 are arranged at the same position in the Z direction.

With this configuration, the internal wiring layer 23C, the first external wiring layer 24C, and the second external wiring layer 25C can be formed in a common process. Therefore, the manufacturing process of the first chip 14 can be simplified.

(1-7) The second internal via 23B of the internal connector 23 and the first substrate side via 24A and second substrate side via 24B of the first external connector 24 are arranged at the same position in the Z direction. The lengths of the second internal via 23B, the first substrate side via 24A, and the second substrate side via 24B in the Z direction are equal to each other.

With this configuration, the second internal via 23B, the first substrate side via 24A, and the second substrate side via 24B can be formed in a common process. Therefore, the manufacturing process of the first chip 14 can be simplified.

(1-8) The first internal via 23A of the internal connector 23 and the first front surface side via 25A and second front surface side via 25B of the second external connector 25 are arranged at the same position in the Z direction. The lengths of the first internal via 23A, the first front surface side via 25A, and the second front surface side via 25B in the Z direction are equal to each other.

With this configuration, the first internal via 23A, the first front surface side via 25A, and the second front surface side via 25B can be formed in a common process. Therefore, the manufacturing process of the first chip 14 can be simplified.

### Second Embodiment

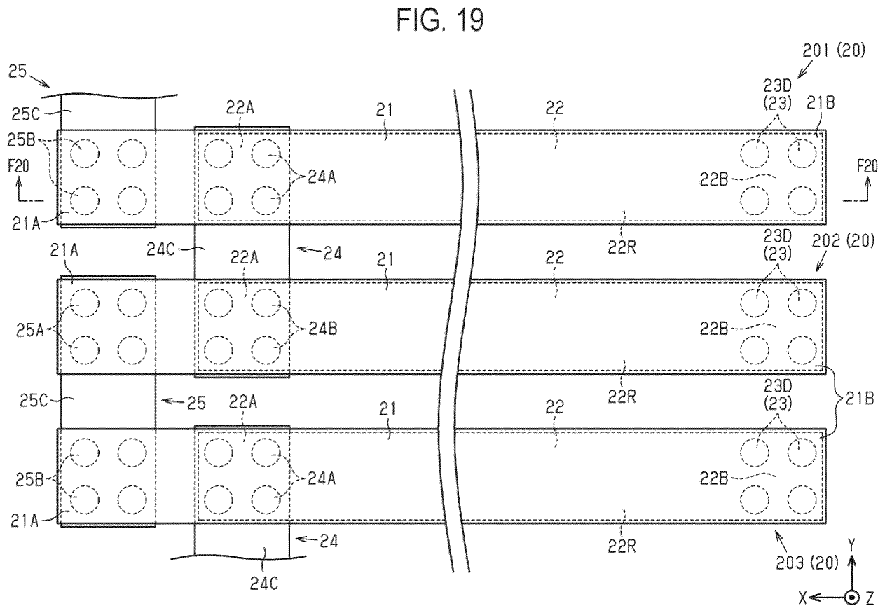

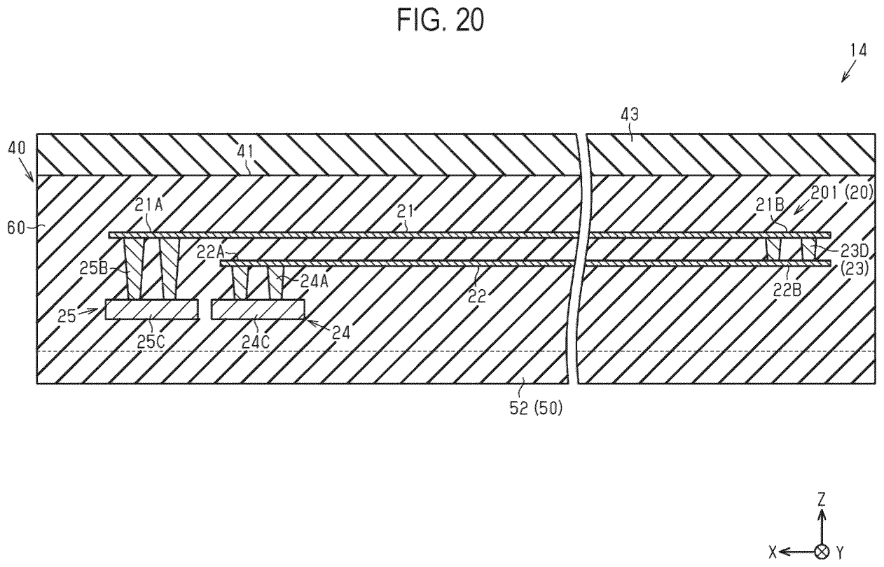

A configuration of a semiconductor module 10 according to a second embodiment will be described with reference to FIGS. 19 and 20. The semiconductor module 10 according to the second embodiment is different from the semiconductor module 10 according to the first embodiment in configurations of the substrate side resistance layer 22 and internal connector 23 of the semiconductor resistance layer 20. Hereinafter, features different from the first embodiment will be described in detail, and constituent elements common with the first embodiment are denoted by the same reference numerals and explanation thereof will be omitted.

### [Connection Configuration of Semiconductor Resistance Layer]

FIG. 19 shows a planar structure of a portion of a plurality of semiconductor resistance layers 20. FIG. 20 shows a cross-sectional structure of the first chip 14, which is taken along line F20-F20 of FIG. 19. Further, in FIG. 19, for ease of understanding the figure, contour lines of components that overlap with each other in a plan view are shown shifted from each other.

As shown in FIGS. 19 and 20, a length dimension of the substrate side resistance layer 22 of the second embodiment (a length of the substrate side resistance layer 22 in the X direction) is longer than the length dimension of the substrate side resistance layer 22 of the first embodiment. The length dimension of the substrate side resistance layer 22 of the second embodiment is shorter than a length dimension of the front surface side resistance layer 21 (a length of the front surface side resistance layer 21 in the X direction).

The second end portion 22B of the substrate side resistance layer 22 is located at a position overlapping with the second end portion 21B of the front surface side resistance layer 21 in a plan view. In one example, an end surface, which is closer to the second end portion 22B, of both end surfaces of the substrate side resistance layer 22 in the X direction, is located at the same position as an end surface, which closer to the second end portion 21B, of both end surfaces of the front surface side resistance layer 21 in the X direction. Therefore, the overlap region 22R of the substrate side resistance layer 22 is formed over the entire substrate side resistance layer 22 in the X direction. Further, in the second embodiment, the overlap region 22R is formed over the entire substrate side resistance layer 22 in the Y direction. As described above, in the second embodiment, the substrate side resistance layer 22 does not have a portion protruding from the front surface side resistance layer 21 in a plan view.

The internal connector 23 of the second embodiment is constituted by an internal via 23D instead of the first internal via 23A, the second internal via 23B, and the internal wiring layer 23C (see FIG. 6) of the first embodiment. The internal via 23D is arranged between the substrate side resistance layer 22 and the front surface side resistance layer 21 in the Z direction.

The internal via 23D connects both the front surface side resistance layer 21 and the overlap region 22R of the substrate side resistance layer 22. In one example, the internal via 23D connects the end portions of the front surface side resistance layer 21 and the substrate side resistance layer 22 in the X direction. In the second embodiment, the internal via 23D connects the second end portion 21B of the front surface side resistance layer 21 and the second end portion 22B of the substrate side resistance layer 22.

The internal via 23D extends in the Z direction. The internal via 23D penetrates the front surface side insulating layer 60 in the Z direction between the front surface side resistance layer 21 and the substrate side resistance layer 22 in the Z direction. As shown in FIGS. 19 and 20, the number of internal vias 23D is four, but is not limited thereto. The number of internal vias 23D can be changed arbitrarily.

### [Method of Manufacturing First Chip]

Next, a method of manufacturing the first chip 14 will be described. Hereinafter, differences from the first embodiment will be described, and explanation of manufacturing processes common with the first embodiment will be omitted.

In the method of manufacturing the first chip 14 according to the second embodiment, as compared to the first embodiment, the process of forming the internal wiring layer 23C, the second internal via 23B, and the first internal via 23A is omitted, and a process of forming the internal via 23D is added. The process of forming the internal via 23D is performed after the third front surface side insulating layer 863 (see FIG. 15) is formed so as to cover the substrate side resistance layer 22 formed on the second front surface side insulating layer 862. In the process of forming the internal via 23D, a via opening is formed in the third front surface side insulating layer 863 by, for example, etching. The via opening exposes the second end portion 22B of the substrate side resistance layer 22 by penetrating the third front surface side insulating layer 863 in the Z direction. Subsequently, the via opening is filled with a metallic material by, for example, sputtering. As the metallic material, one or more of, for example, Ti, TiN, Ta, TaN, Au, Ag, Cu, Al, and W are appropriately selected. As a result, the internal via 23D is formed. After the internal via 23D is formed, the front surface side resistance layer 21 is formed on the third front surface side insulating layer 863. As a result, the second end portion 21B of the front surface side resistance layer 21 is connected to the internal via 23D. The subsequent processes are generally the same as those in the first embodiment.

### [Effects]

According to the second embodiment, the following effects can be achieved.

(2-1) The internal connector 23 is constituted by the internal via 23D connected to both the front surface side resistance layer 21 and the overlap region 22R of the substrate side resistance layer 22.

With this configuration, as compared to a configuration including, as the internal connector 23, a via connected to the substrate side resistance layer 22, a via connected to the front surface side resistance layer 21, and a wiring layer connected to these vias, a connection structure between the front surface side resistance layer 21 and the substrate side resistance layer 22 can be simplified.

(2-2) The internal via 23D connects the second end portions 21B and 22B of the front surface side resistance layer 21 and the substrate side resistance layer 22 in the X direction. With this configuration, it is possible to lengthen a current path of one semiconductor resistance layer 20 constituted by the front surface side resistance layer 21, the substrate side resistance layer 22, and the internal via 23D.

### Third Embodiment

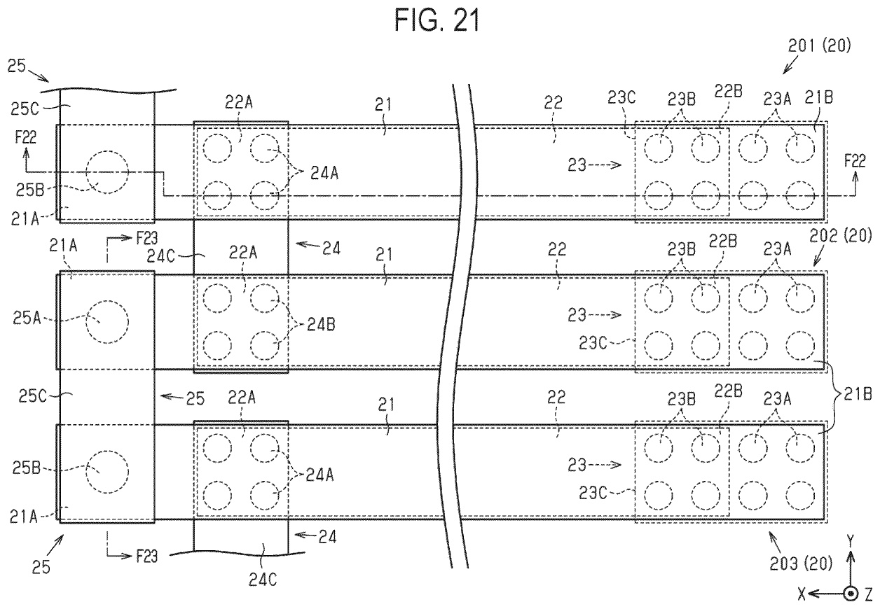

A configuration of a semiconductor module 10 according to a third embodiment will be described with reference to FIGS. 21 to 23. The semiconductor module 10 according to the third embodiment is different from the semiconductor module 10 according to the first embodiment in a configuration of the second external connector 25 in the first chip 14. Hereinafter, features different from the first embodiment will be described in detail, and constituent elements common with the first embodiment are denoted by the same reference numerals and explanation thereof will be omitted.

### [Connection Configuration of Semiconductor Resistance Layer]

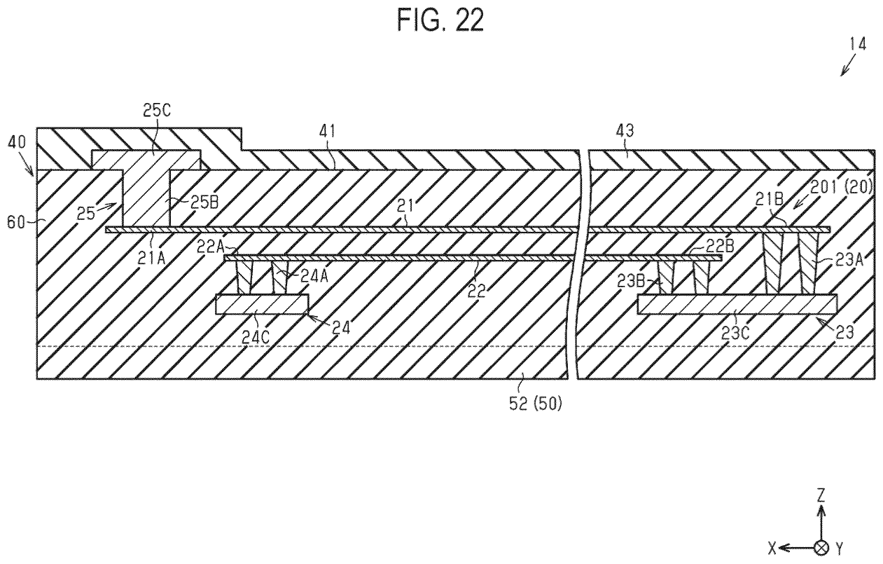

FIG. 21 shows a planar structure of a portion of a plurality of semiconductor resistance layers 20. FIG. 22 shows a cross-sectional structure of the first chip 14, which is taken along line F22-F22 of FIG. 21. Further, in FIG. 21, for ease of understanding the figure, contour lines of components that overlap with each other in a plan view are shown shifted from each other.

As shown in FIGS. 21 and 22, the second external connector 25 is located on the opposite side to the substrate side resistance layer 22 with respect to the front surface side resistance layer 21 of the semiconductor resistance layer 20 in the Z direction. As in the first embodiment, the second external connector 25 is located at a position overlapping with the first end portion 21A of the front surface side resistance layer 21 in a plan view.

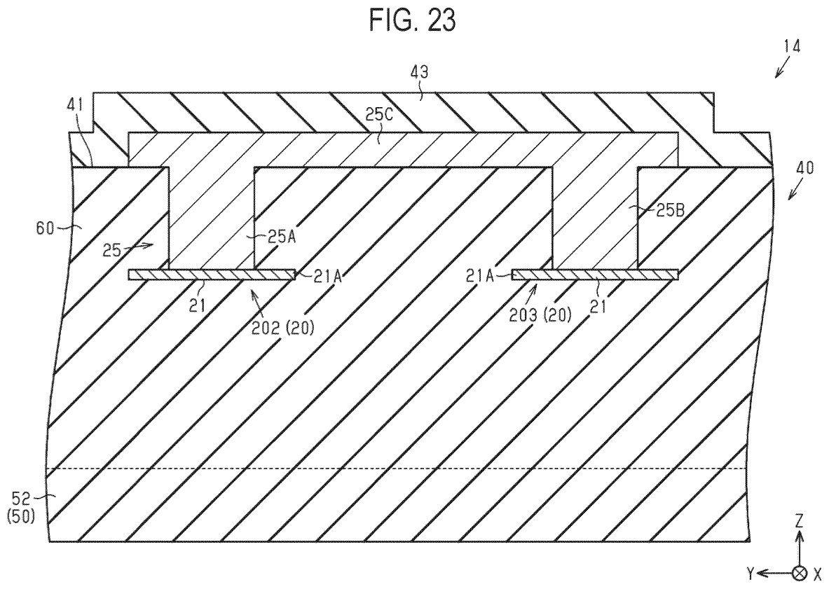

As shown in FIGS. 22 and 23, in the second external connector 25 of the third embodiment, the first front surface side via 25A, the second front surface side via 25B, and the second external wiring layer 25C are integrally formed. The second external connector 25 is formed of a material containing at least one of, for example, Ti, TiN, Ta, TaN, Au, Ag, Cu, Al, or W. In one example, the second external connector 25 is formed of a material containing Al.

The first front surface side via 25A is connected to the first end portion 21A of the front surface side resistance layer 21 of the second semiconductor resistance layer 202. The second front surface side via 25B is connected to the first end portion 21A of the front surface side resistance layer 21 of the third semiconductor resistance layer 203. In the illustrated example, there is one first front surface side via 25A and one second front surface side via 25B, but the number is not limited thereto. The number of each of the first front surface side vias 25A and the second front surface side vias 25B can be arbitrarily changed.

The second external wiring layer 25C is arranged on the opposite side to the substrate side resistance layer 22 with respect to the front surface side resistance layer 21 in the Z direction. The second external wiring layer 25C is formed on the element front surface 41 of the element insulating layer 40. The second external wiring layer 25C is covered with the passivation film 43. A portion of the front surface side insulating layer 60 is interposed between the second external wiring layer 25C and the front surface side resistance layer 21 in the Z direction. Therefore, both the first front surface side via 25A and the second front surface side via 25B penetrate the front surface side insulating layer 60 in the Z direction interposed between the second external wiring layer 25C and the front surface side resistance layer 21 in the Z direction.

### [Method of Manufacturing First Chip]

Next, a method of manufacturing the first chip 14 will be described. Hereinafter, differences from the first embodiment will be described, and explanation of manufacturing processes common with the first embodiment will be omitted.

The method of manufacturing the first chip 14 of the third embodiment is different from that of the first embodiment in the process of manufacturing the second external connector 25. In the third embodiment, the process of forming the second external connector 25 is performed after the fourth front surface side insulating layer 864 (see FIG. 17) covering the front surface side resistance layer 21 is formed.

The process of forming the second external connector 25 includes a process of forming the first front surface side via 25A and the second front surface side via 25B, which are connected to the front surface side resistance layer 21, in the fourth front surface side insulating layer 864. More specifically, first, a first via opening and a second via opening are formed in the fourth front surface side insulating layer 864 by, for example, etching. Subsequently, the first via opening and the second via opening are filled with a metallic material by, for example, sputtering. As the metallic material, one or more of, for example, Ti, TiN, Ta, TaN, Au, Ag, Cu, Al, and W are appropriately selected. As a result, the first front surface side via 25A and the second front surface side via 25B are formed.

The process of forming the second external connector 25 includes a process of forming the second external wiring layer 25C that connects the first front surface side via 25A and the second front surface side via 25B. In this process, first, a metal layer is formed on the fourth front surface side insulating layer 864 by, for example, sputtering. As the metal layer, one or more of, for example, Ti, TiN, Ta, TaN, Au, Ag, Cu, Al, and W are appropriately selected. Subsequently, the second external wiring layer 25C is formed by patterning the metal layer. Through the above processes, the second external connector 25 is manufactured.

Thereafter, the passivation film 843 (see FIG. 18) is formed on the fourth front surface side insulating layer 864 so as to cover the second external wiring layer 25C. The subsequent processes are generally the same as those in the first embodiment.

### [Effects]

According to the third embodiment, the following effects can be achieved.

(3-1) The second external wiring layer 25C is arranged on the opposite side to the substrate side resistance layer 22 with respect to the front surface side resistance layer 21 in the Z direction.

With this configuration, the second external connector 25 being located at the same position as the first external connector 24 in the Z direction is avoided. The second external connector 25 is prevented from overlapping with the first external connector 24 when viewed from the X direction. Therefore, it is possible to improve a degree of freedom in setting the length of the front surface side resistance layer 21 in the X direction and the length of the substrate side resistance layer 22 in the X direction.

### Fourth Embodiment

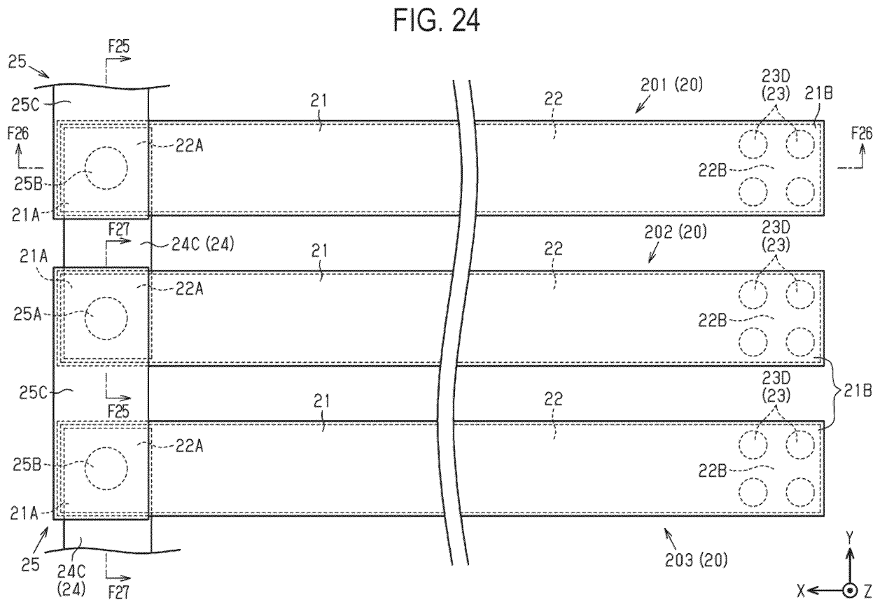

A configuration of a semiconductor module 10 according to a fourth embodiment will be described with reference to FIGS. 24 to 27. The semiconductor module 10 according to the fourth embodiment is different from the semiconductor module 10 according to the second embodiment in configurations of the substrate side resistance layer 22, the first external connector 24, and the second external connector 25 of the semiconductor resistance layer 20. Hereinafter, features different from the second embodiment will be described in detail, and constituent elements common with the second embodiment are denoted by the same reference numerals and explanation thereof will be omitted.

### [Connection Configuration of Semiconductor Resistance Layer]

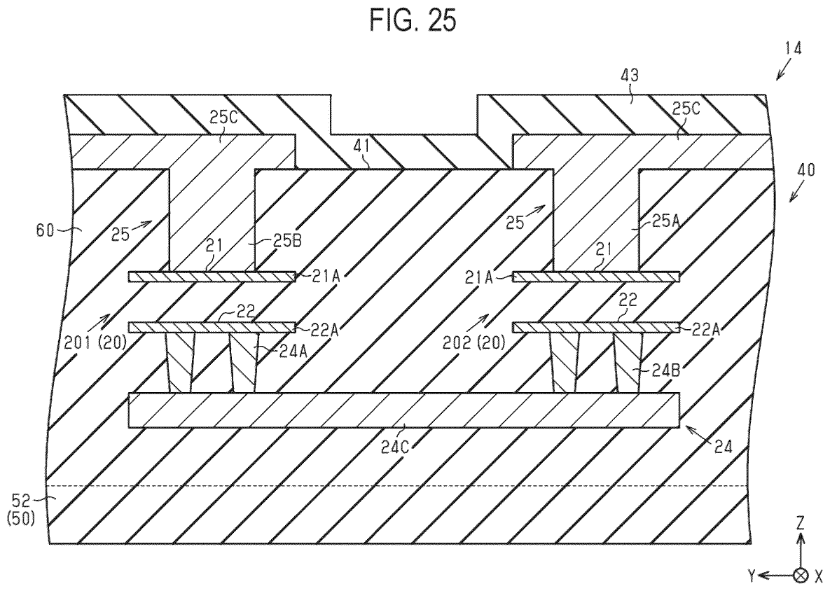

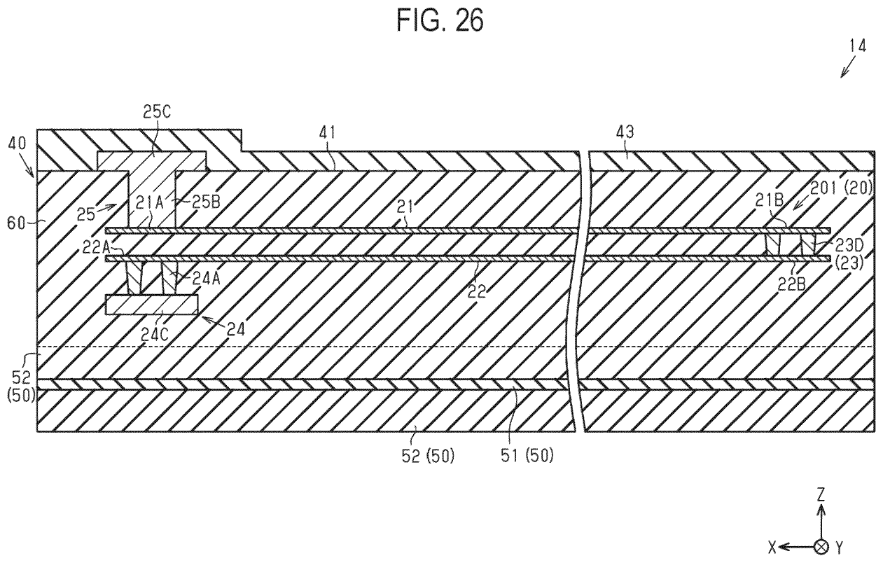

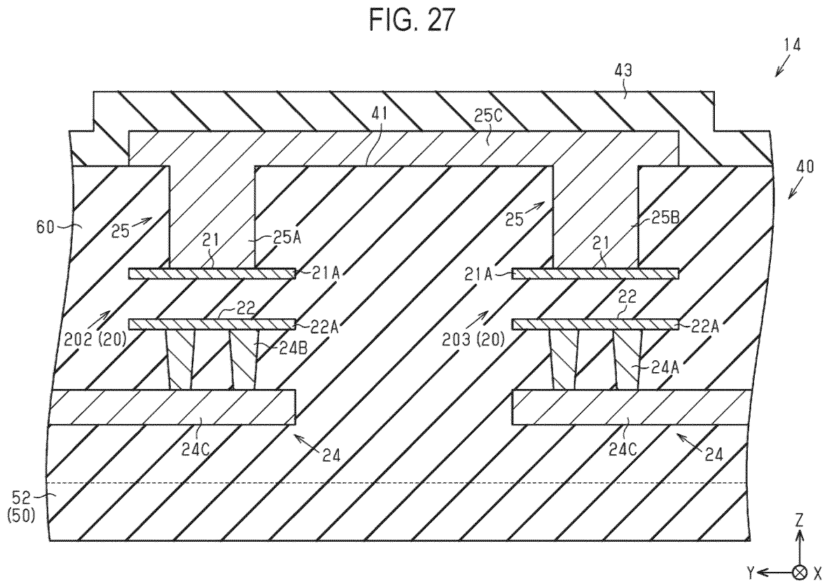

FIG. 24 shows a planar structure of a portion of a plurality of semiconductor resistance layers 20. FIG. 25 shows a cross-sectional structure of the first chip 14, which is taken along line F25-F25 of FIG. 24. FIG. 26 shows a cross-sectional structure of the first chip 14, which is taken along line F26-F26 of FIG. 24. FIG. 27 shows a cross-sectional structure of the first chip 14, which is taken along line F27-F27 of FIG. 24. Further, in FIG. 24, for ease of understanding the figure, contour lines of components that overlap with each other in a plan view are shown shifted from each other.

As shown in FIG. 24, the first external connector 24 of the fourth embodiment is located at a different position in the X direction, as compared to the second embodiment. Specifically, the first external connector 24 is located at a position overlapping with the second external connector 25 in a plan view. In other words, the first external connector 24 is located at a position overlapping with the first end portion 21A of the front surface side resistance layer 21 of the semiconductor resistance layer 20. That is, the first external connector 24 and the second external connector 25 are provided at the first end portion 21A of the front surface side resistance layer 21 so as to overlap with each other in a plan view.

As shown in FIG. 25, the first external connector 24 connects the first end portions 22A of the substrate side resistance layers 22 of two semiconductor resistance layers 20 adjacent to each other in the Y direction. Therefore, the first end portion 22A is arranged at a position overlapping with the first end portion 21A of the front surface side resistance layer 21 in a plan view. As shown in FIG. 26, in the fourth embodiment, the length dimension of the substrate side resistance layer 22 (the length of the substrate side resistance layer 22 in the X direction) is equal to the length dimension of the front surface side resistance layer 21 (the length of the front surface side resistance layer 21 in the X direction). Here, when a difference between the length dimension of the substrate side resistance layer 22 and the length dimension of the front surface side resistance layer 21 is within, for example, 10% of the length dimension of the front surface side resistance layer 21, it can be said that the length dimension of the substrate side resistance layer 22 is equal to the length dimension of the front surface side resistance layer 21.

As shown in FIG. 27, the second external connector 25 connects the first end portions 21A of the front surface side resistance layers 21 of two semiconductor resistance layers 20 adjacent to each other in the Y direction. As shown in FIGS. 25 and 27, in the first external connector 24 and the second external connector 25, two semiconductor resistance layers 20 that are electrically connected to each other are shifted by one.

As shown in FIG. 27, the configuration of the second external connector 25 of the fourth embodiment is the same as the configuration of the second external connector 25 of the third embodiment. In one example, the material of the first front surface side via 25A and the second front surface side via 25B of the second external connector 25 is different from the material of the first substrate side via 24A and the second substrate side via 24B of the first external connector 24.

### [Method of Manufacturing First Chip]

Next, a method of manufacturing the first chip 14 will be described. Hereinafter, differences from the first embodiment will be described, and explanation of manufacturing processes common with the first embodiment will be omitted.

In the method of manufacturing the first chip 14 of the fourth embodiment, as compared to the first embodiment, the process of forming the internal wiring layer 23C, the second internal via 23B, and the first internal via 23A is omitted, and a process of forming the internal via 23D is added. Further, the method of manufacturing the first chip 14 of the fourth embodiment is different from that of the first embodiment in the process of manufacturing the second external connector 25. The process of forming the internal via 23D is the same as the process of forming the internal via 23D of the second embodiment. The process of forming the second external connector 25 is the same as the process of forming the second external connector 25 of the third embodiment.

### [Effects]

According to the fourth embodiment, the following effects can be achieved.

(4-1) In the X direction, the length of the front surface side resistance layer 21 and the length of the substrate side resistance layer 22 are equal to each other. With this configuration, within a range of the first chip 14 in the X direction, each of the length of the front surface side resistance layer 21 in the X direction and the length of the substrate side resistance layer 22 in the X direction can be extended to the maximum.

(4-2) The first external connector 24 and the second external connector 25 are provided in the first end portion 21A of the front surface side resistance layer 21 so as to overlap with each other in a plan view. With this configuration, it is possible to lengthen a current path in each of the front surface side resistance layer 21 and the substrate side resistance layer 22.

### Fifth Embodiment

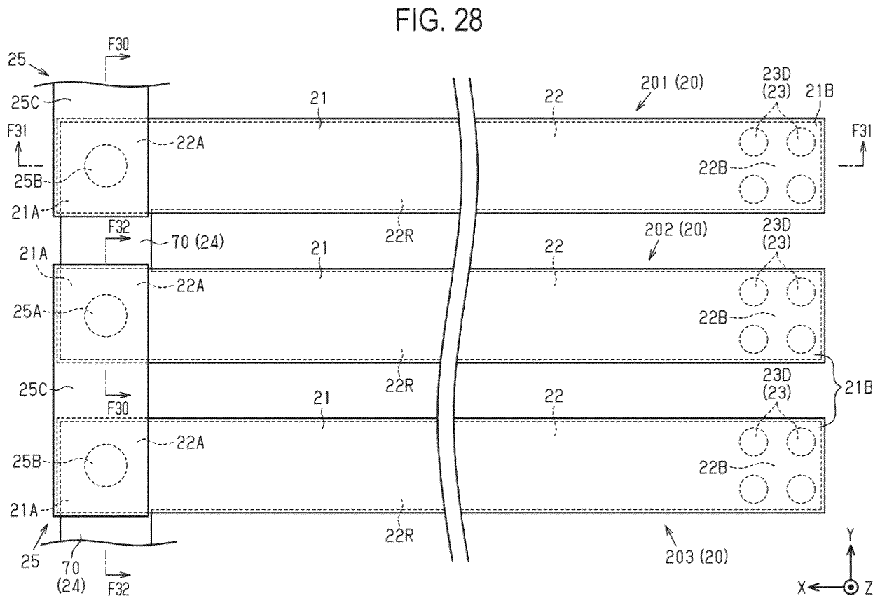

A configuration of a semiconductor module 10 according to a fifth embodiment will be described with reference to FIGS. 28 to 32. The semiconductor module 10 according to the fifth embodiment is different from the semiconductor module 10 according to the second embodiment in configurations of the substrate side resistance layer 22, the first external connector 24, and the second external connector 25 of the semiconductor resistance layer 20. Hereinafter, features different from the second embodiment will be described in detail, and constituent elements common with the second embodiment are denoted by the same reference numerals and explanation thereof will be omitted.

### [Connection Configuration of Semiconductor Resistance Layer]

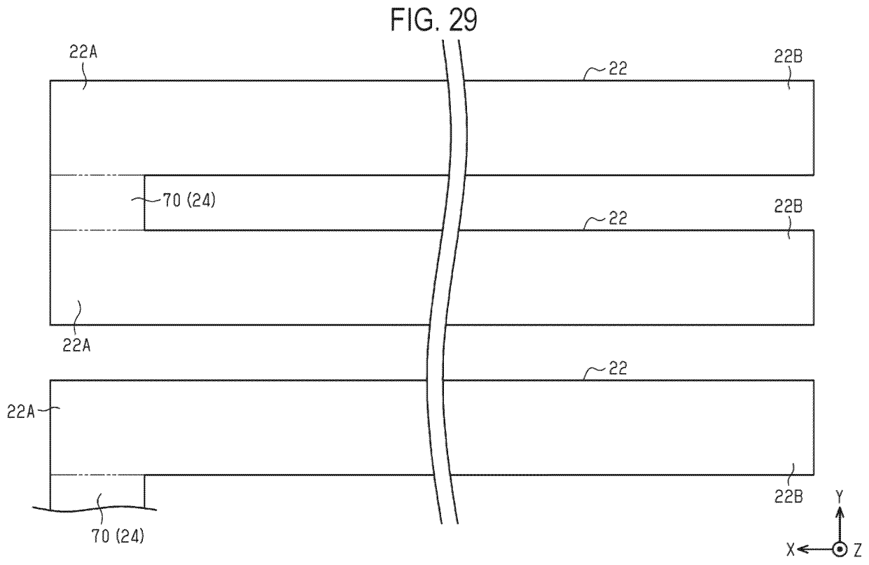

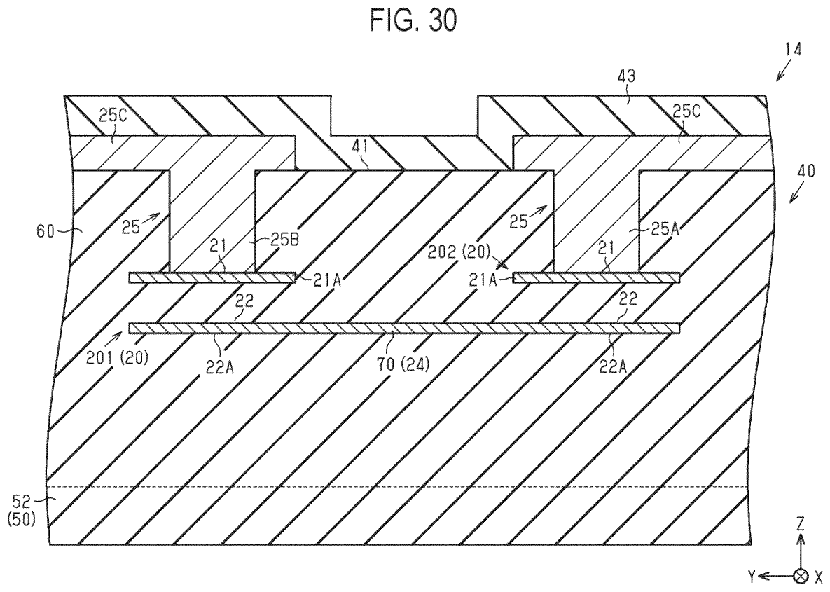

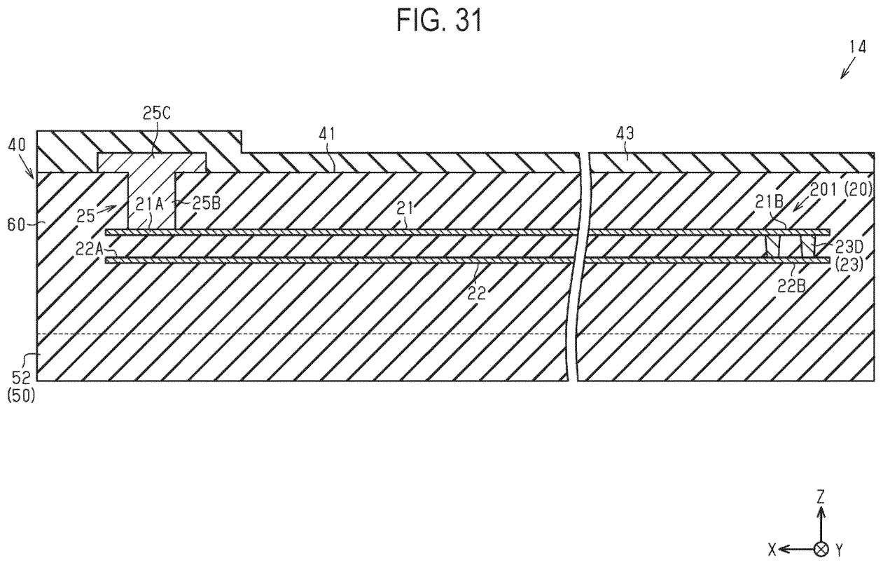

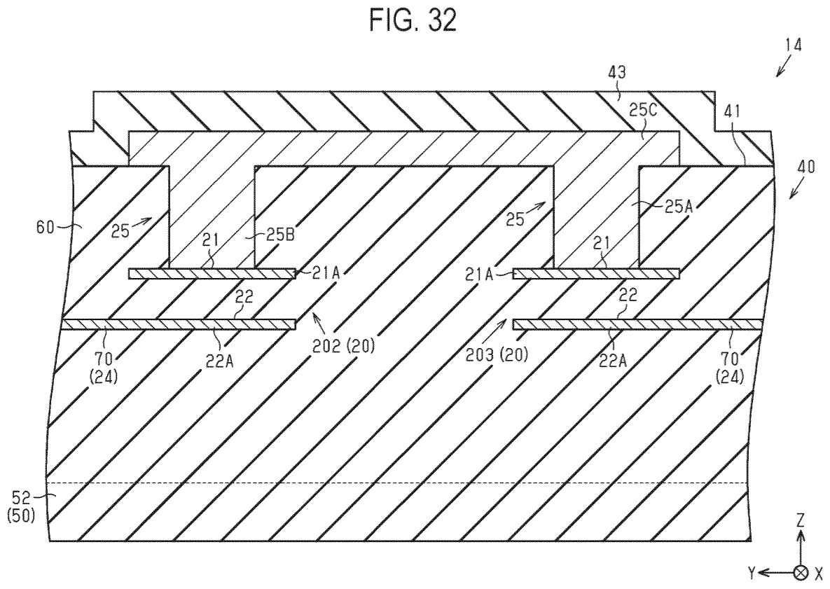

FIG. 28 shows a planar structure of a plurality of semiconductor resistance layers 20, and FIG. 29 shows a planar structure of a plurality of substrate side resistance layers 22. FIG. 30 shows a cross-sectional structure of the first chip 14, which is taken along line F30-F30 of FIG. 28. FIG. 31 shows a cross-sectional structure of the first chip 14, which is taken along line F31-F31 of FIG. 28. FIG. 32 shows a cross-sectional structure of the first chip 14, which is taken along line F32-F32 of FIG. 28. Further, in FIG. 28, for ease of understanding the figure, contour lines of components that overlap with each other in a plan view are shown shifted from each other.

As shown in FIGS. 28 and 29, the first external connector 24 of the fifth embodiment is located at a different position in the X direction, as compared to the second embodiment. Specifically, the first external connector 24 is located at a position overlapping with the second external connector 25 in a plan view. In other words, the first external connector 24 is located at a position overlapping with the first end portion 21A of the front surface side resistance layer 21 of the semiconductor resistance layer 20. That is, the first external connector 24 and the second external connector 25 are provided at the first end portion 21A of the front surface side resistance layer 21 so as to overlap with each other in a plan view.

As shown in FIG. 29, the first external connector 24 of the fifth embodiment includes a connection wiring layer 70 instead of the first substrate side via 24A, the second substrate side via 24B, and the first external wiring layer 24C (see FIG. 8). The connection wiring layer 70 is provided between two substrate side resistance layers 22 adjacent to each other in the Y direction and is provided integrally with these substrate side resistance layers 22. The connection wiring layer 70 is formed so as to connect the first end portions 22A of these substrate side resistance layers 22. In one example, a width dimension of the connection wiring layer 70 (a size of the connection wiring layer 70 in the X direction) is equal to the width dimension of the substrate side resistance layer 22 (the size of the substrate side resistance layer 22 in the Y direction). Here, when a difference between the width dimension of the connection wiring layer 70 and the width dimension of the substrate side resistance layer 22 is within, for example, 10% of the width dimension of the substrate side resistance layer 22, it can be said that the width dimension of the connection wiring layer 70 is equal to the width dimension of the substrate side resistance layer 22. Further, the width dimension of the connection wiring layer 70 can be changed arbitrarily. Further, in FIG. 29, for ease of understanding the figure, a boundary between the first end portion 22A of the substrate side resistance layer 22 and the connection wiring layer 70 is indicated by a two-dot chain line.

As shown in FIG. 30, the connection wiring layer 70 is provided at the same position as the substrate side resistance layer 22 in the Z direction. Further, a thickness of the connection wiring layer 70 is equal to the thickness of the substrate side resistance layer 22. Here, when a difference between the thickness of the connection wiring layer 70 and the thickness of the substrate side resistance layer 22 is within, for example, 10% of the thickness of the substrate side resistance layer 22, it can be said that the thickness of the connection wiring layer 70 is equal to the thickness of the substrate side resistance layer 22. The connection wiring layer 70 is formed of the same material as the substrate side resistance layer 22. In one example, the connection wiring layer 70 is formed of a material containing CrSi.

As shown in FIG. 31, the front surface side resistance layer 21 and the substrate side resistance layer 22 are electrically connected in series by connecting the second end portion 21B of the front surface side resistance layer 21 and the second end portion 22B of the substrate side resistance layer 22 by the internal via 23D. As described above, the length dimension of the substrate side resistance layer 22 is equal to the length dimension of the front surface side resistance layer 21.

As shown in FIGS. 31 and 32, the second external connector 25 of the fifth embodiment has the same configuration as the second external connector 25 of the third embodiment. In one example, the material of the second external connector 25 and the material of the first external connector 24 are different from each other.

### [Method of Manufacturing First Chip]

Next, a method of manufacturing the first chip 14 will be described. Hereinafter, differences from the fourth embodiment will be described, and explanation of manufacturing processes common with the fourth embodiment will be omitted.

The method of manufacturing the first chip 14 of the fifth embodiment is different from that of the fourth embodiment in the process of forming the first external connector 24. In the method of manufacturing the first chip 14 of the fifth embodiment, the process of forming the first external wiring layer 24C and the process of forming the first substrate side via 24A and the second substrate side via 24B are omitted, and a process of forming the connection wiring layer 70 is added.

The process of forming the connection wiring layer 70 is performed in the same process as the process of forming the substrate side resistance layer 22. That is, the substrate side resistance layer 22 and the connection wiring layer 70 are formed integrally. Therefore, the method of manufacturing the first chip 14 includes a process of forming the substrate side resistance layer 22 and the connection wiring layer 70 on the second front surface side insulating layer 862 (see FIG. 14). Therefore, the connection wiring layer 70 is formed of the same material as the substrate side resistance layer 22. The subsequent processes are the same as those in the fourth embodiment.

### [Effects]

According to the fifth embodiment, the following effects can be achieved.

(5-1) The first external connector 24 is provided at the same position as the substrate side resistance layer 22 of the first semiconductor resistance layer 201 and the substrate side resistance layer 22 of the second semiconductor resistance layer 202 in the Z direction, and includes the connection wiring layer 70 that connects both the substrate side resistance layers 22.

With this configuration, as compared to a configuration including, as the first external connector 24, a via connected to the substrate side resistance layer 22 of the first semiconductor resistance layer 201, a via connected to the substrate side resistance layer 22 of the second semiconductor resistance layer 202, and a wiring layer connected to these vias, the connection configuration between the substrate side resistance layer 22 of the first semiconductor resistance layer 201 and the substrate side resistance layer 22 of the second semiconductor resistance layer 202 can be simplified.

(5-2) Each of the internal connector 23, the first external connector 24, and the second external connector 25 is provided at the same position as the substrate side resistance layer 22 in the Z direction, or at a position on the opposite side to the substrate 30 with respect to the substrate side resistance layer 22.

With this configuration, it is possible to increase a distance between the substrate 30 and each of the internal connector 23, the first external connector 24, and the second external connector 25 in the Z direction. Therefore, the dielectric breakdown voltage of the first chip 14 can be improved.

(5-3) The connection wiring layer 70 is formed integrally with the substrate side resistance layer 22. With this configuration, the first external connector 24 and the substrate side resistance layer 22 can be easily formed as compared to a case where the first external connector 24 is formed as a component separate from the substrate side resistance layer 22. Therefore, the manufacturing process of the first chip 14 can be simplified.

(5-4) The connection wiring layer 70 is formed of the same material as the substrate side resistance layer 22. With this configuration, the connection wiring layer 70 can be constituted as a portion of the substrate side resistance layer 22. Therefore, since the connection wiring layer 70 can constitute a portion of the semiconductor resistance layer 20, it is possible to increase the length of the semiconductor resistance layer 20.

### Sixth Embodiment

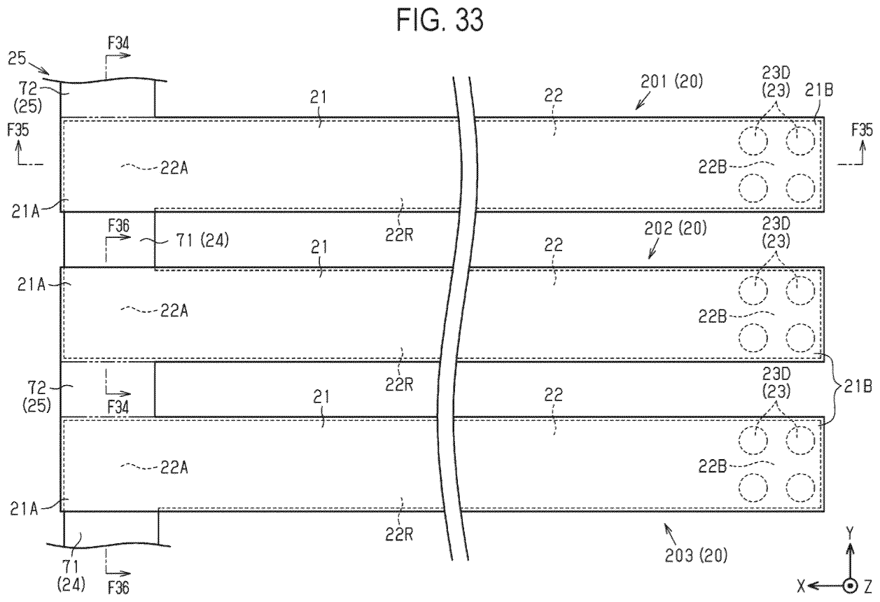

A configuration of a semiconductor module 10 according to a sixth embodiment will be described with reference to FIGS. 33 to 36. The semiconductor module 10 according to the sixth embodiment is different from the semiconductor module 10 according to the fifth embodiment in configurations of the front surface side resistance layer 21 and the second external connector 25 of the semiconductor resistance layer 20. Hereinafter, features different from the fifth embodiment will be described in detail, and constituent elements common with the fifth embodiment are denoted by the same reference numerals and explanation thereof will be omitted.

### [Connection Configuration of Semiconductor Resistance Layer]

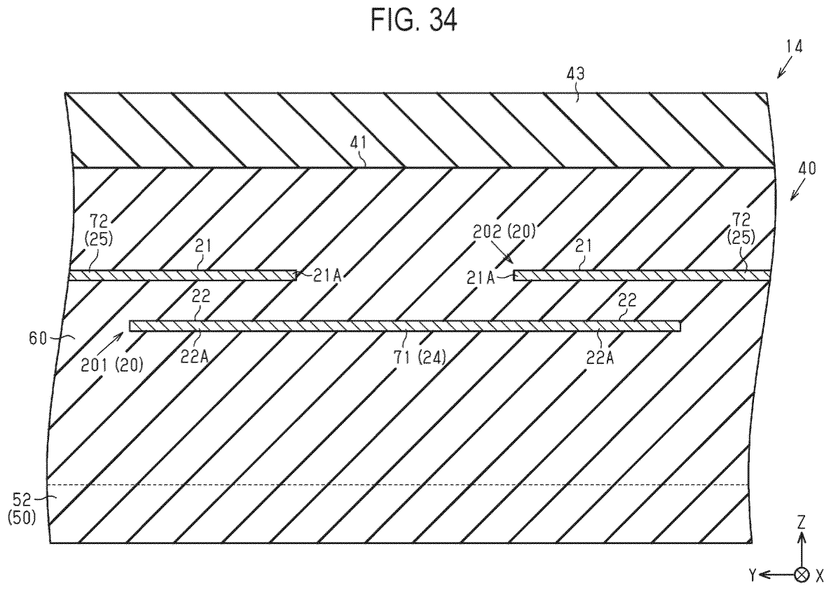

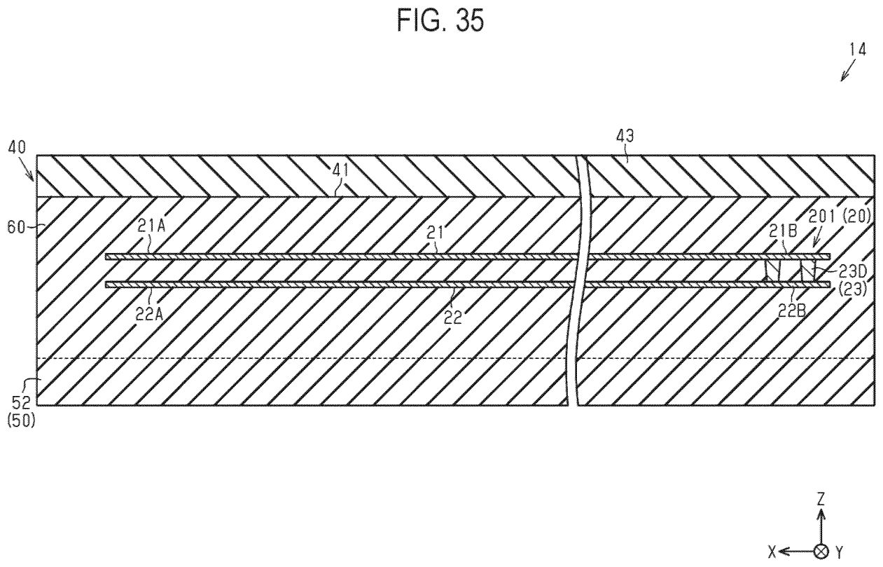

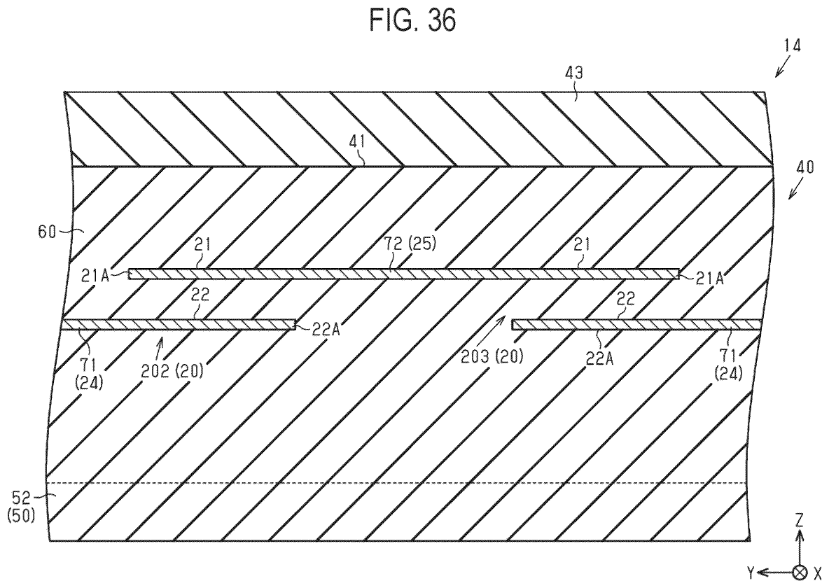

FIG. 33 shows a planar structure of a plurality of semiconductor resistance layers 20. FIG. 34 shows a cross-sectional structure of the first chip 14, which is taken along line F34-F34 of FIG. 33. FIG. 35 shows a cross-sectional structure of the first chip 14, which is taken along line F35-F35 of FIG. 33. FIG. 36 shows a cross-sectional structure of the first chip 14, which is taken along line F36-F36 of FIG. 33. Further, in FIG. 33, for ease of understanding the figure, contour lines of components that overlap with each other in a plan view are shown shifted from each other.

As shown in FIGS. 33 and 35, the internal connector 23 of the sixth embodiment is the same as the internal connector 23 of the fifth embodiment (the second embodiment). Further, as in the fifth embodiment, the length of the front surface side resistance layer 21 in the X direction and the length of the substrate side resistance layer 22 in the X direction are equal to each other. Further, the overlap region 22R of the substrate side resistance layer 22 is formed over the entire substrate side resistance layer 22 in the X direction. Further, the overlap region 22R is formed over the entire substrate side resistance layer 22 in the Y direction.

As shown in FIG. 34, the first external connector 24 of the sixth embodiment is the same as the first external connector 24 of the fifth embodiment. In the sixth embodiment, for the sake of convenience of explanation, the connection wiring layer 70 in the first external connector 24 of the fifth embodiment is referred to as a “first connection wiring layer 71.” Therefore, the first external connector 24 is provided at the same position as the substrate side resistance layer 22 of the first semiconductor resistance layer 201 and the substrate side resistance layer 22 of the second semiconductor resistance layer 202 in the Z direction, and includes the first connection wiring layer 71 that connects both the substrate side resistance layers 22.

As shown in FIGS. 33 and 36, the second external connector 25 of the sixth embodiment includes a second connection wiring layer 72 instead of the first front surface side via 25A, the second front surface side via 25B, and the second external wiring layer 25C (see FIG. 32). The second connection wiring layer 72 is provided between two front surface side resistance layers 21 adjacent to each other in the Y direction and is provided integrally with these front surface side resistance layers 21. In one example, as shown in FIG. 33, the front surface side resistance layer 21 of the second semiconductor resistance layer 202 and the front surface side resistance layer 21 of the third semiconductor resistance layer 203 are connected to each other. Further, in FIG. 33, for ease of understanding the figure, a boundary between the first end portion 21A of the front surface side resistance layer 21 and the second connection wiring layer 72 is indicated by a two-dot chain line.

The second connection wiring layer 72 is formed so as to connect the first end portions 21A of these front surface side resistance layers 21. The first connection wiring layer 71 and the second connection wiring layer 72 are provided at positions overlapping with each other in a plan view in the first end portion 21A of the front surface side resistance layer 21.

In one example, a width dimension of the second connection wiring layer 72 (a size of the second connection wiring layer 72 in the X direction) is equal to the width dimension of the front surface side resistance layer 21 (the size of the front surface side resistance layer 21 in the Y direction). Here, when a difference between the width dimension of the second connection wiring layer 72 and the width dimension of the front surface side resistance layer 21 is within, for example, 10% of the width dimension of the front surface side resistance layer 21, it can be said that the width dimension of the second connection wiring layer 72 is equal to the width dimension of the front surface side resistance layer 21. Further, in one example, the width dimension of the second connection wiring layer 72 is equal to the width dimension of the first connection wiring layer 71. Here, when a difference between the width dimension of the second connection wiring layer 72 and the width dimension of the first connection wiring layer 71 is within, for example, 10% of the width dimension of the first connection wiring layer 71, it can be said that the width dimension of the second connection wiring layer 72 is equal to the width dimension of the first connection wiring layer 71. Further, in one example, a length dimension of the second connection wiring layer 72 (a length of the second connection wiring layer 72 in the Y direction) is equal to the length dimension of the first connection wiring layer 71 (the length of the first connection wiring layer 71 in the Y direction). Here, when a difference between the length dimension of the second connection wiring layer 72 and the length dimension of the first connection wiring layer 71 is within, for example, 10% of the length dimension of the first connection wiring layer 71, it can be said that the length dimension of the second connection wiring layer 72 is equal to the length dimension of the first connection wiring layer 71. Further, each of the width dimension and length dimension of the second connection wiring layer 72 can be changed arbitrarily.

As shown in FIG. 36, the second connection wiring layer 72 is provided at the same position as the front surface side resistance layer 21 in the Z direction. Further, a thickness of the second connection wiring layer 72 is equal to the thickness of the front surface side resistance layer 21. Here, when a difference between the thickness of the second connection wiring layer 72 and the thickness of the front surface side resistance layer 21 is within 10% of the thickness of the front surface side resistance layer 21, it can be said that the thickness of the second connection wiring layer 72 is equal to the thickness of the front surface side resistance layer 21. Further, the thickness of the second connection wiring layer 72 is equal to the thickness of the first connection wiring layer 71. Here, when a difference between the thickness of the second connection wiring layer 72 and the thickness of the first connection wiring layer 71 is within, for example, 10% of the thickness of the first connection wiring layer 71, it can be said that the thickness of the second connection wiring layer 72 is equal to the thickness of the first connection wiring layer 71.

The second connection wiring layer 72 is formed of the same material as the front surface side resistance layer 21. In one example, the second connection wiring layer 72 is formed of a material containing CrSi. Further, the second connection wiring layer 72 may be formed of the same material as the first connection wiring layer 71. Therefore, the second connection wiring layer 72 may be formed of the same material as the substrate side resistance layer 22.

### [Method of Manufacturing First Chip]

Next, a method of manufacturing the first chip 14 will be described. Hereinafter, differences from the fourth embodiment will be described, and explanation of manufacturing processes common with the fourth embodiment will be omitted.

The method of manufacturing the first chip 14 of the sixth embodiment is different from that of the fourth embodiment in the process of forming the first external connector 24 and the process of forming the second external connector 25. In the method of manufacturing the first chip 14 of the sixth embodiment, the process of forming the first external wiring layer 24C and the process of forming the first substrate side via 24A and the second substrate side via 24B are omitted, and a process of forming the first connection wiring layer 71 is added. In the method of manufacturing the first chip 14 of the sixth embodiment, the process of forming the second external wiring layer 25C and the process of forming the first front surface side via 25A and the second front surface side via 25B are omitted, and a process of forming the second connection wiring layer 72 is added.

The process of forming the first connection wiring layer 71 is performed in the same process as the process of forming the substrate side resistance layer 22. That is, the substrate side resistance layer 22 and the first connection wiring layer 71 are formed integrally. Therefore, the method of manufacturing the first chip 14 includes a process of forming the substrate side resistance layer 22 and the first connection wiring layer 71 on the second front surface side insulating layer 862 (see FIG. 14). Therefore, the first connection wiring layer 71 is formed of the same material as the substrate side resistance layer 22.

The process of forming the second connection wiring layer 72 is performed in the same process as the process of forming the front surface side resistance layer 21. That is, the front surface side resistance layer 21 and the second connection wiring layer 72 are formed integrally. Therefore, the method of manufacturing the first chip 14 includes a process of forming the front surface side resistance layer 21 and the second connection wiring layer 72 on the third front surface side insulating layer 863 (see FIG. 15). Therefore, the second connection wiring layer 72 is formed of the same material as the front surface side resistance layer 21. The subsequent processes are the same as those in the fourth embodiment.

### [Effects]

According to the sixth embodiment, the following effects can be achieved.

(6-1) The first external connector 24 is provided at the same position as the substrate side resistance layer 22 of the first semiconductor resistance layer 201 and the substrate side resistance layer 22 of the second semiconductor resistance layer 202 in the Z direction, and includes the first connection wiring layer 71 that connects both the substrate side resistance layers 22. The second external connector 25 is provided at the same position as the front surface side resistance layer 21 of the second semiconductor resistance layer 202 and the front surface side resistance layer 21 of the third semiconductor resistance layer 203 in the Z direction, and includes the second connection wiring layer 72 that connects both the front surface side resistance layers 21.

With this configuration, as compared to a configuration including, as the first external connector 24, a via connected to the substrate side resistance layer 22 of the first semiconductor resistance layer 201, a via connected to the substrate side resistance layer 22 of the second semiconductor resistance layer 202, and a wiring layer connected to these vias, the connection configuration between the substrate side resistance layer 22 of the first semiconductor resistance layer 201 and the substrate side resistance layer 22 of the second semiconductor resistance layer 202 can be simplified. Further, as compared to a configuration including, as the second external connector 25, a via connected to the front surface side resistance layer 21 of the second semiconductor resistance layer 202, a via connected to the front surface side resistance layer 21 of the third semiconductor resistance layer 203, and a wiring layer connected to these vias, the connection configuration between the front surface side resistance layer 21 of the second semiconductor resistance layer 202 and the front surface side resistance layer 21 of the third semiconductor resistance layer 203 can be simplified.

(6-2) The first connection wiring layer 71 and the second connection wiring layer 72 are provided at positions overlapping with each other in a plan view in the first end portion 21A of the front surface side resistance layer 21. With this configuration, it is possible to lengthen a current path in each of the front surface side resistance layer 21 and the substrate side resistance layer 22.

(6-3) Each of the internal connector 23, the first external connector 24, and the second external connector 25 is provided at the same position as the substrate side resistance layer 22 in the Z direction, or at a position on the opposite side to the substrate 30 with respect to the substrate side resistance layer 22.

With this configuration, it is possible to increase a distance between the substrate 30 and each of the internal connector 23, the first external connector 24, and the second external connector 25 in the Z direction. Therefore, the dielectric breakdown voltage of the first chip 14 can be improved.

(6-4) The first connection wiring layer 71 is formed integrally with the substrate side resistance layer 22. The second connection wiring layer 72 is formed integrally with the front surface side resistance layer 21. With this configuration, the first external connector 24 and the substrate side resistance layer 22 can be easily formed as compared to a case where the first external connector 24 is formed as a component separate from the substrate side resistance layer 22. The second external connector 25 and the front surface side resistance layer 21 can be easily formed as compared to a case where the second external connector 25 is formed as a component separate from the front surface side resistance layer 21. Therefore, the manufacturing process of the first chip 14 can be simplified.

(6-5) The first connection wiring layer 71 is formed of the same material as the substrate side resistance layer 22. The second connection wiring layer 72 is formed of the same material as the front surface side resistance layer 21. With this configuration, the first connection wiring layer 71 can be constituted as a portion of the substrate side resistance layer 22, and the second connection wiring layer 72 can be constituted as a portion of the front surface side resistance layer 21. Therefore, since both the first connection wiring layer 71 and the second connection wiring layer 72 can constitute a portion of the semiconductor resistance layer 20, it is possible to increase the length of the semiconductor resistance layer 20.

### Modifications

Each of the above-described embodiments can be modified and implemented as follows. Further, each of the above-described embodiments and the following modifications can be implemented in combination unless technically contradictory.

The first to sixth embodiments can be combined with one another within a scope that is not technically contradictory. In one example, in the third embodiment, the internal via 23D of the second embodiment may be combined as the internal connector 23. With this configuration, the effect (2-1) of the second embodiment can be obtained.

In one example, in the fifth embodiment, the configuration of the second external connector 25 of the first embodiment may be applied as the configuration of the second external connector 25. In this case, the length of the front surface side resistance layer 21 in the X direction is longer than the length of the substrate side resistance layer 22 in the X direction. In other words, the first end portion 21A of the front surface side resistance layer 21 is shifted from the first end portion 22A of the substrate side resistance layer 22 in the X direction so that the second external connector 25 is provided to be shifted in the X direction with respect to the first external connector 24.

In one example, in the sixth embodiment, the configuration of the first external connector 24 of the first embodiment may be applied as the configuration of the first external connector 24. In one example, in the fourth to sixth embodiments, the internal connector 23 of the first or third embodiment may be combined as the internal connector 23.

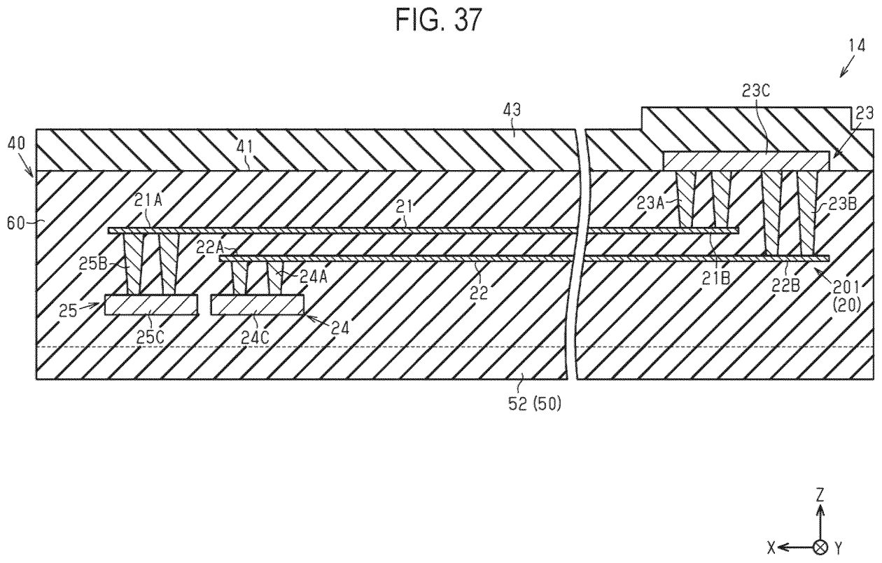

In the first and third embodiments, the configuration of the internal connector 23 can be changed arbitrarily. In one example, as shown in FIG. 37, the internal wiring layer 23C of the internal connector 23 may be arranged on the opposite side to the substrate side resistance layer 22 with respect to the front surface side resistance layer 21 in the Z direction. In one example, the internal wiring layer 23C is arranged on the element front surface 41 of the element insulating layer 40. The internal wiring layer 23C is covered with the passivation film 43.

As shown in FIG. 37, the second end portion 22B of the substrate side resistance layer 22 is provided at a position protruding from the second end portion 21B of the front surface side resistance layer 21 in the X direction. That is, the substrate side resistance layer 22 includes a protruding portion that protrudes from the front surface side resistance layer 21 in the X direction in a plan view. This protruding portion includes the second end portion 22B of the substrate side resistance layer 22.

The first internal via 23A is connected to the second end portion 21B of the front surface side resistance layer 21. The first internal via 23A is provided on the opposite side to the substrate side resistance layer 22 with respect to the front surface side resistance layer 21 in the Z direction. The first internal via 23A is connected to the internal wiring layer 23C.

The second internal via 23B is connected to the second end portion 22B of the substrate side resistance layer 22. A length of the second internal via 23B in the Z direction is longer than a length of the first internal via 23A in the Z direction. The second internal via 23B is connected to the internal wiring layer 23C. As described above, the internal wiring layer 23C may be provided closer to the element front surface 41 than the substrate side resistance layer 22.

In the third embodiment, the position of the first end portion 22A of the substrate side resistance layer 22 in the X direction can be changed arbitrarily. In one example, the first end portion 22A of the substrate side resistance layer 22 may be provided at a position overlapping with the first end portion 21A of the front surface side resistance layer 21 in a plan view.

In the fourth to sixth embodiments, each of the length of the front surface side resistance layer 21 in the X direction and the length of the substrate side resistance layer 22 in the X direction can be changed arbitrarily. In one example, the length of the front surface side resistance layer 21 in the X direction may be longer than the length of the substrate side resistance layer 22 in the X direction. Further, in one example, the length of the substrate side resistance layer 22 in the X direction may be longer than the length of the front surface side resistance layer 21 in the X direction.

In the fifth embodiment, the connection wiring layer 70 may be formed of a material different from that of the substrate side resistance layer 22.

In the fifth embodiment, the position of the connection wiring layer 70 in the X direction can be changed arbitrarily. In one example, the connection wiring layer 70 may be arranged closer to the second end portion 22B of the substrate side resistance layer 22 than the second external connector 25.

In the fifth embodiment, the position of the connection wiring layer 70 in the Z direction can be changed arbitrarily. In one example, the connection wiring layer 70 may be arranged at a different position from the substrate side resistance layer 22 in the Z direction. In one example, the connection wiring layer 70 may be arranged closer to the substrate 30 than the substrate side resistance layer 22 in the Z direction.

In the sixth embodiment, the position of the first connection wiring layer 71 in the X direction can be changed arbitrarily. In one example, the first connection wiring layer 71 may be arranged closer to the second end portion 22B of the substrate side resistance layer 22 than the second connection wiring layer 72.

In the sixth embodiment, the position of the first connection wiring layer 71 in the Z direction can be changed arbitrarily. In one example, the first connection wiring layer 71 may be arranged at a different position from the substrate side resistance layer 22 in the Z direction. In one example, the first connection wiring layer 71 may be arranged closer to the substrate 30 than the substrate side resistance layer 22 in the Z direction.

In the sixth embodiment, the position of the second connection wiring layer 72 in the X direction can be changed arbitrarily. In one example, the second connection wiring layer 72 may be arranged closer to the second end portion 21B of the front surface side resistance layer 21 than the first connection wiring layer 71.

In the sixth embodiment, the position of the second connection wiring layer 72 in the Z direction can be changed arbitrarily. In one example, the second connection wiring layer 72 may be arranged at a different position from the front surface side resistance layer 21 in the Z direction. In one example, the second connection wiring layer 72 may be arranged on the opposite side to the substrate side resistance layer 22 with respect to the front surface side resistance layer 21 in the Z direction.

In the sixth embodiment, the first connection wiring layer 71 may be formed of a material different from that of the substrate side resistance layer 22.

In the sixth embodiment, the second connection wiring layer 72 may be formed of a material different from that of the front surface side resistance layer 21.

In each embodiment, a relationship between the width dimension of the front surface side resistance layer 21 and the width dimension of the substrate side resistance layer 22 can be changed arbitrarily. In one example, the width dimension of the front surface side resistance layer 21 may be larger than the width dimension of the substrate side resistance layer 22. In one example, the width dimension of the front surface side resistance layer 21 may be smaller than the width dimension of the substrate side resistance layer 22.

In each embodiment, a relationship between the thickness of the front surface side resistance layer 21 and the thickness of the substrate side resistance layer 22 can be changed arbitrarily. In one example, the front surface side resistance layer 21 may be thicker than the substrate side resistance layer 22. Further, in one example, the front surface side resistance layer 21 may be thinner than the substrate side resistance layer 22.

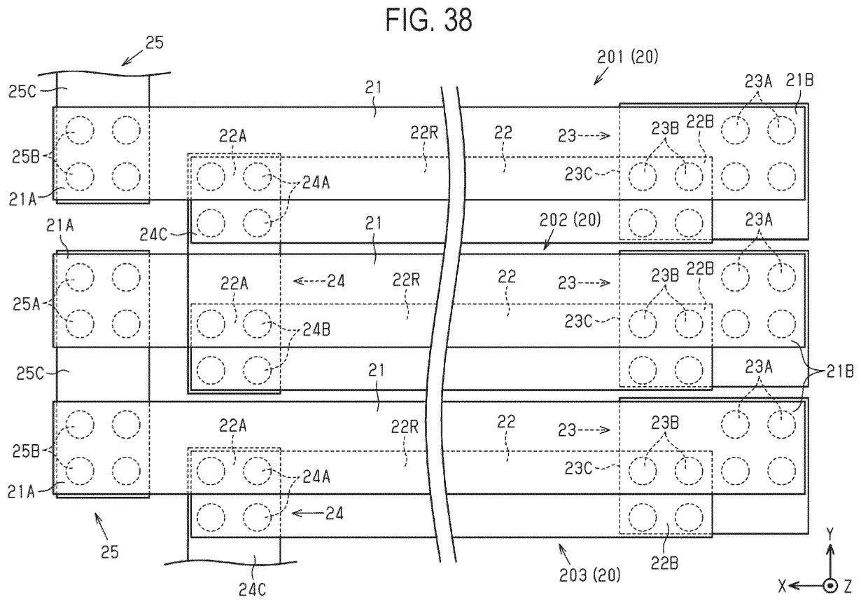

In each embodiment, an arrangement relationship between the front surface side resistance layer 21 and the substrate side resistance layer 22 in the Y direction can be changed arbitrarily. In one example, as shown in FIG. 38, the substrate side resistance layer 22 may be arranged at a position partially shifted from the front surface side resistance layer 21 in the Y direction. That is, the overlap region 22R of the substrate side resistance layer 22 is provided in a portion of the substrate side resistance layer 22 in the Y direction. In other words, the substrate side resistance layer 22 includes a protruding portion that protrudes from the front surface side resistance layer 21 in the Y direction in a plan view.

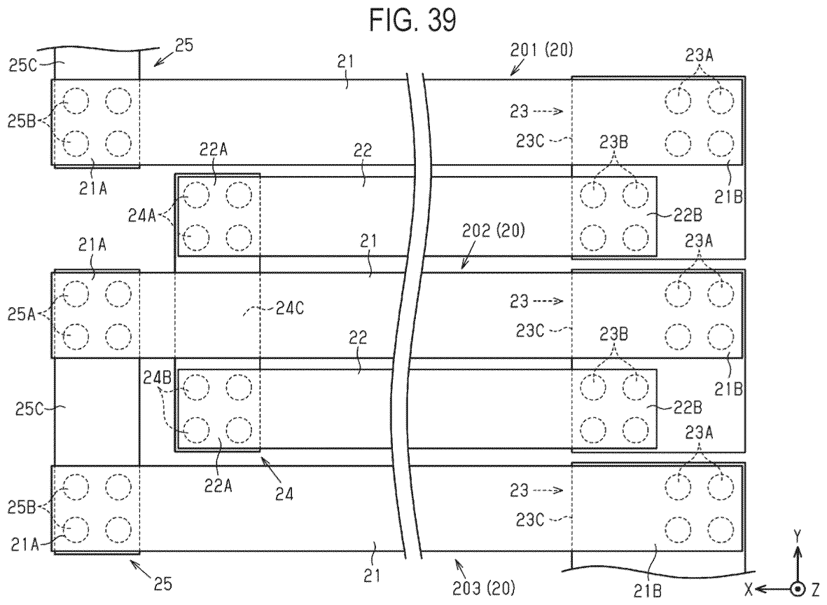

In another example, as shown in FIG. 39, the entire substrate side resistance layer 22 may be arranged at a position shifted from the front surface side resistance layer 21 in the Y direction. That is, it is not necessary that the substrate side resistance layer 22 has a portion that overlaps with the front surface side resistance layer 21 in a plan view. In other words, it is not necessary that the substrate side resistance layer 22 includes the overlap region 22R (see FIG. 38).

In each embodiment, an arrangement relationship between the front surface side resistance layer 21 and the substrate side resistance layer 22 in the X direction can be changed arbitrarily. In one example, the substrate side resistance layer 22 may include a protruding portion that protrudes from the front surface side resistance layer 21 in the X direction.

In each embodiment, the number of semiconductor resistance layers 20 can be changed arbitrarily. In one example, the number of semiconductor resistance layers 20 may be one. When the number of semiconductor resistance layers 20 is one, the semiconductor resistance layer 20 may be formed in, for example, a bellows shape in a plan view.

In each embodiment, the position of the internal connector 23 in the X direction can be changed arbitrarily. In one example, the internal connector 23 may be provided closer to a center of the substrate side resistance layer 22 in the X direction than the second end portion 22B of the substrate side resistance layer 22. The internal connector 23 may be provided closer to a center of the front surface side resistance layer 21 in the X direction than the second end portion 21B of the front surface side resistance layer 21.

In each embodiment, the position of the first external connector 24 in the X direction can be changed arbitrarily. In one example, the first external connector 24 may be provided closer to the center of the substrate side resistance layer 22 in the X direction than the first end portion 22A of the substrate side resistance layer 22.

In each embodiment, the position of the second external connector 25 in the X direction can be changed arbitrarily. In one example, the second external connector 25 may be provided closer to the center of the front surface side resistance layer 21 in the X direction than the first end portion 21A of the front surface side resistance layer 21.

In each embodiment, the configuration of the substrate side insulating layer 50 can be changed arbitrarily. In one example, the substrate side insulating layer 50 may be formed of the interlayer insulating film 52 without including the etching stopper film 51.

In each embodiment, the passivation film 43 may be omitted from the first chip 14.

In each embodiment, the number of semiconductor chips included in the semiconductor module 10 can be changed arbitrarily. In one example, the semiconductor module 10 may include a third chip in addition to the first chip 14 and the second chip 15. The third chip is electrically connected to at least one of the first chip 14 or the second chip 15 by a wire, for example.

In each embodiment, the second chip 15 may be omitted from the semiconductor module 10. In this case, the die pad 12 may be omitted from the semiconductor module 10. Further, the semiconductor module 10 may include three leads, which are individually connected to the terminals P3 to P5 of the first chip 14 by the wires W3 to W5, instead of the leads 13A to 13G. The leads 13A to 13G may be omitted from the semiconductor module 10. That is, the semiconductor module 10 may include the first chip 14 (semiconductor device), the frame 11 that supports the first chip 14, and the sealing resin 16 that seals the first chip 14 and the frame 11.

One or more of the various examples described in the present disclosure can be combined unless technically contradictory. As used in the present disclosure, the term “on” includes the meanings of “on” and “over” unless clearly stated otherwise in the context. Therefore, the expression “A is formed on B” is intended that in each of the above-described embodiments, A can be arranged directly on B and in contact with B, but as a modification, A can be arranged over B without being in contact with B. That is, the term “on” does not exclude a structure in which other members are formed between A and B.

It is not necessary that the Z direction used in the present disclosure is the vertical direction, and it is not necessary that the Z direction is exactly the same as the vertical direction. Therefore, various structures according to the present disclosure are not limited to “up” and “down” in the Z direction described herein as being “up” and “down” in the vertical direction. For example, the X direction may be the vertical direction, or the Y direction may be the vertical direction.

### Supplementary Notes

The technical ideas that can be recognized from each of the above-described embodiments and modifications are described below. In addition, for the purpose of aiding understanding and not for the purpose of limitation, components described in supplementary notes are labeled with the reference numerals of the corresponding components in the embodiments. The reference numerals are provided as examples to aid understanding, and the components described in supplementary notes should not be limited to the components indicated by the reference numerals.

### [Supplementary Note 1]

A semiconductor device (14) including:
a substrate (30);
an element insulating layer (40) provided on the substrate (30); and
a semiconductor resistance layer (20) provided on the element insulating layer (40),
wherein the semiconductor resistance layer (20) includes:
   a front surface side resistance layer (21) extending in a first direction (X direction) perpendicular to a thickness direction (Z direction) of the substrate (30);
   a substrate side resistance layer (22) arranged closer to the substrate (30) than the front surface side resistance layer (21) in the thickness direction (Z direction); and
   an internal connector (23) that electrically connects the front surface side resistance layer (21) and the substrate side resistance layer (22) in series.

### [Supplementary Note 2]

The semiconductor device of Supplementary Note 1, wherein the substrate side resistance layer (22) includes an overlap region (22R) that overlaps with the front surface side resistance layer (21) when viewed from the thickness direction (Z direction).

### [Supplementary Note 3]

The semiconductor device of Supplementary Note 2, wherein the overlap region (22R) is formed over an entirety of the substrate side resistance layer (22) in the first direction (X direction).

### [Supplementary Note 4]

The semiconductor device of any one of Supplementary Notes 1 to 3, wherein in the first direction (X direction), the front surface side resistance layer (21) is longer than the substrate side resistance layer (22).

### [Supplementary Note 5]

The semiconductor device of any one of Supplementary Notes 1 to 4, wherein the internal connector (23) includes:
a first internal via (23A) connected to the front surface side resistance layer (21);
a second internal via (23B) provided at a different position from the first internal via (23A) in the first direction (X direction) and connected to the substrate side resistance layer (22); and
an internal wiring layer (23C) arranged at a different position from both the front surface side resistance layer (21) and the substrate side resistance layer (22) in the thickness direction (Z direction) and connected to both the first internal via (23A) and the second internal via (23B).

### [Supplementary Note 6]

The semiconductor device of Supplementary Note 2 or 3, wherein the internal connector (23) includes an internal via (23D) connected to both the front surface side resistance layer (21) and the overlap region (22R) of the substrate side resistance layer (22).

### [Supplementary Note 7]

The semiconductor device of Supplementary Note 6, wherein both the front surface side resistance layer (21) and the substrate side resistance layer (22) have a first end portion (21A, 22A) and a second end portion (21B, 22B), which are both end portions in the first direction (X direction), and
wherein the internal via (23D) connects the second end portions (21B, 22B) of the front surface side resistance layer (21) and the substrate side resistance layer (22) in the first direction (X direction).

### [Supplementary Note 8]

The semiconductor device of any one of Supplementary Notes 1 to 7, wherein the semiconductor resistance layer includes a plurality of semiconductor resistance layers (20) arranged to be spaced apart from one another in a second direction (Y direction) perpendicular to the first direction (X direction) when viewed from the thickness direction (Z direction),
wherein the plurality of semiconductor resistance layers (20) includes a first semiconductor resistance layer (201), a second semiconductor resistance layer (202), and a third semiconductor resistance layer (203), which are adjacent to one another in the second direction (Y direction), and
wherein the semiconductor device further includes:
   a first external connector (24) that electrically connects the substrate side resistance layer (22) of the first semiconductor resistance layer (201) and the substrate side resistance layer (22) of the second semiconductor resistance layer (202), which are adjacent to each other in the second direction (Y direction); and
   a second external connector (25) that electrically connects the front surface side resistance layer (21) of the second semiconductor resistance layer (202) and the front surface side resistance layer (21) of the third semiconductor resistance layer (203), which are adjacent to each other in the second direction (Y direction).

### [Supplementary Note 9]

The semiconductor device of Supplementary Note 8, wherein the first external connector (24) includes:
a first substrate side via (24A) connected to the substrate side resistance layer (22) of the first semiconductor resistance layer (201);
a second substrate side via (24B) connected to the substrate side resistance layer (22) of the second semiconductor resistance layer (202); and
a first external wiring layer (24C) extending in the second direction (Y direction) and connected to both the first substrate side via (24A) and the second substrate side via (24B).

### [Supplementary Note 10]

The semiconductor device of Supplementary Note 8 or 9, wherein the second external connector (25) includes:
a first front surface side via (25A) connected to the front surface side resistance layer (21) of the second semiconductor resistance layer (202);
a second front surface side via (25B) connected to the front surface side resistance layer (21) of the third semiconductor resistance layer (203); and
a second external wiring layer (25C) extending in the second direction (Y direction) and connected to both the first front surface side via (25A) and the second front surface side via (25B).

### [Supplementary Note 11]

The semiconductor device of any one of Supplementary Notes 8 to 10, wherein both the front surface side resistance layer (21) and the substrate side resistance layer (22) have a first end portion (21A, 22A) and a second end portion (21B, 22B), which are both end portions in the first direction (X direction),
wherein the internal connector (23) is provided at the second end portion (21B) of the front surface side resistance layer (21) and the second end portion (22B) of the substrate side resistance layer (22), and
wherein both the first external connector (24) and the second external connector (25) are located closer to the first end portion (21A, 22A) than a center of the semiconductor resistance layer (20) in the first direction (X direction).

### [Supplementary Note 12]

The semiconductor device of any one of Supplementary Notes 8 to 11, wherein the second external connector (25) is located on an opposite side to the substrate side resistance layer (22) with respect to the front surface side resistance layer (21) in the thickness direction (Z direction).

### [Supplementary Note 13]

The semiconductor device of Supplementary Note 12, wherein both the front surface side resistance layer (21) and the substrate side resistance layer (22) have a first end portion (21A, 22A) and a second end portion (21B, 22B), which are both end portions in the first direction (X direction), and
wherein the first external connector (24) and the second external connector (25) are provided so as to overlap with each other when viewed from the thickness direction (Z direction) at the first end portion (21A) of the front surface side resistance layer (21).

### [Supplementary Note 14]

The semiconductor device of Supplementary Note 8, wherein the first external connector (24) is provided at the same position as the substrate side resistance layer (22) of the first semiconductor resistance layer (201) and the substrate side resistance layer (22) of the second semiconductor resistance layer (202) in the thickness direction (Z direction), and includes a connection wiring layer (70) that connects both the substrate side resistance layers (22).

### [Supplementary Note 15]

The semiconductor device of Supplementary Note 8, wherein the first external connector (24) is provided at the same position as the substrate side resistance layer (22) of the first semiconductor resistance layer (201) and the substrate side resistance layer (22) of the second semiconductor resistance layer (202) in the thickness direction (Z direction), and includes a first connection wiring layer (71) that connects both the substrate side resistance layers (22), and
wherein the second external connector (25) is provided at the same position as the front surface side resistance layer (21) of the second semiconductor resistance layer (202) and the front surface side resistance layer (21) of the third semiconductor resistance layer (203) in the thickness direction (Z direction), and includes a second connection wiring layer (72) that connects both the front surface side resistance layers (21).

### [Supplementary Note 16]

The semiconductor device of Supplementary Note 15, wherein both the front surface side resistance layer (21) and the substrate side resistance layer (22) have a first end portion (21A, 22A) and a second end portion (21B, 22B), which are both end portions in the first direction (X direction), and
wherein the first connection wiring layer (71) and the second connection wiring layer (72) are provided at positions overlapping with each other when viewed from the thickness direction (Z direction) at the first end portion (21A) of the front surface side resistance layer (21).

### [Supplementary Note 17]

The semiconductor device of any one of Supplementary Notes 1 to 16, wherein in the first direction (X direction), a length of the front surface side resistance layer (21) and a length of the substrate side resistance layer (22) are equal to each other.

### [Supplementary Note 18]

The semiconductor device of any one of Supplementary Notes 1 to 17, wherein when viewed from the thickness direction (Z direction), a width dimension of the front surface side resistance layer (21) and a width dimension of the substrate side resistance layer (22) are equal to each other.

### [Supplementary Note 19]

The semiconductor device of any one of Supplementary Notes 1 to 18, wherein a thickness of the front surface side resistance layer (21) and a thickness of the substrate side resistance layer (22) are equal to each other.

### [Supplementary Note 20]

The semiconductor device of any one of Supplementary Notes 1 to 19, wherein the element insulating layer (40) includes:
a substrate side insulating layer (50) provided on the substrate (30); and
a front surface side insulating layer (60) stacked on the substrate side insulating layer (50),
wherein the substrate side insulating layer (50) has a structure in which a plurality of first insulating films (51) and a plurality of second insulating films (52) that relieves a stress of the first insulating films (51) are alternately stacked one by one, and
wherein the semiconductor resistance layer (20) is embedded in the front surface side insulating layer (60).

### [Supplementary Note 21]

The semiconductor device of Supplementary Note 10, wherein the second external wiring layer (25C) is provided on the element insulating layer (40) and is covered with a passivation film (43).

### [Supplementary Note 22]

The semiconductor device of Supplementary Note 14, wherein the connection wiring layer (70) is formed of the same material as the substrate side resistance layer (22).

### [Supplementary Note 23]

The semiconductor device of Supplementary Note 15, wherein the first connection wiring layer (71) is formed of the same material as the substrate side resistance layer (22), and
wherein the second connection wiring layer (72) is formed of the same material as the front surface side resistance layer (21).

### [Supplementary Note 24]

The semiconductor device of Supplementary Note 23, wherein the first connection wiring layer (71) is formed integrally with the substrate side resistance layer (22), and
wherein the second connection wiring layer (72) is formed integrally with the front surface side resistance layer (21).

### [Supplementary Note 25]

The semiconductor device of any one of Supplementary Notes 1 to 24, wherein the internal connector (23) is located on an opposite side to the substrate side resistance layer (22) with respect to the front surface side resistance layer (21) in the thickness direction (Z direction).

### [Supplementary Note 26]

A semiconductor module (10) includes:
a semiconductor device (14) of any one of Supplementary Notes 1 to 25;
a support (11) that supports the semiconductor device (14); and
a sealing resin (16) that seals the semiconductor device (14) and the support (11).

### [Supplementary Note 27]

A method of manufacturing a semiconductor device (14), including:
forming a substrate side insulating layer (850) on a substrate (830);
forming a first front surface side insulating layer (861) on the substrate side insulating layer (850);
forming a first external wiring layer (24C), a second external wiring layer (25C), and an internal wiring layer (23C) on the first front surface side insulating layer (861);
forming a second front surface side insulating layer (862) on the first front surface side insulating layer (861) so as to cover the first external wiring layer (24C), the second external wiring layer (25C), and the internal wiring layer (23C);
forming a first substrate side via (24A) and a second substrate side via (24B), which are connected to the first external wiring layer (24C), and a second internal via (23B), which is connected to the internal wiring layer (23C), in the second front surface side insulating layer (862);
forming a substrate side resistance layer (22) on the second front surface side insulating layer (862);
forming a third front surface side insulating layer (863) on the second front surface side insulating layer (862) so as to cover the substrate side resistance layer (22);
forming a first front surface side via (25A) and a second front surface side via (25B), which are connected to the second external wiring layer (25C), and a first internal via (23A), which is connected to the internal wiring layer (23C), in the third front surface side insulating layer (863) and the second front surface side insulating layer (862);
forming a front surface side resistance layer (21) on the third front surface side insulating layer (863); and
forming a fourth front surface side insulating layer (864) on the third front surface side insulating layer (863) so as to cover the front surface side resistance layer (21).

### [Supplementary Note 28]

A method of manufacturing a semiconductor device (14), including:
forming a substrate side insulating layer (850) on a substrate (830);
forming a first front surface side insulating layer (861) on the substrate side insulating layer (850);
forming a first external wiring layer (24C) and a second external wiring layer (25C) on the first front surface side insulating layer (861);
forming a second front surface side insulating layer (862) on the first front surface side insulating layer (861) so as to cover the first external wiring layer (24C) and the second external wiring layer (25C);
forming a first substrate side via (24A) and a second substrate side via (24B), which are connected to the first external wiring layer (24C), in the second front surface side insulating layer (862);
forming a substrate side resistance layer (22) on the second front surface side insulating layer (862);
forming a third front surface side insulating layer (863) on the second front surface side insulating layer (862) so as to cover the substrate side resistance layer (22);
forming an internal via (23D), which is connected to the substrate side resistance layer (22), in the third front surface side insulating layer (863);
forming a first front surface side via (25A) and a second front surface side via (25B), which are connected to the second external wiring layer (25C), in the third front surface side insulating layer (863) and the second front surface side insulating layer (862);
forming a front surface side resistance layer (21) on the third front surface side insulating layer (863); and
forming a fourth front surface side insulating layer (864) on the third front surface side insulating layer (863) so as to cover the front surface side resistance layer (21).

### [Supplementary Note 29]

A method of manufacturing a semiconductor device (14), including:
forming a substrate side insulating layer (850) on a substrate (830);
forming a first front surface side insulating layer (861) on the substrate side insulating layer (850);
forming a first external wiring layer (24C) and an internal wiring layer (23C) on the first front surface side insulating layer (861);
forming a second front surface side insulating layer (862) on the first front surface side insulating layer (861) so as to cover the first external wiring layer (24C) and the internal wiring layer (23C);
forming a first substrate side via (24A) and a second substrate side via (24B), which are connected to the first external wiring layer (24C), and a second internal via (23B), which is connected to the internal wiring layer (23C), in the second front surface side insulating layer (862);
forming a substrate side resistance layer (22) on the second front surface side insulating layer (862);
forming a third front surface side insulating layer (863) on the second front surface side insulating layer (862) so as to cover the substrate side resistance layer (22);
forming a first internal via (23A), which is connected to the internal wiring layer (23C), in the third front surface side insulating layer (863) and the second front surface side insulating layer (862);
forming a front surface side resistance layer (21) on the third front surface side insulating layer (863);
forming a fourth front surface side insulating layer (864) on the third front surface side insulating layer (863) so as to cover the front surface side resistance layer (21);
forming a first front surface side via (25A) and a second front surface side via (25B), which are connected to the front surface side resistance layer (21), in the fourth front surface side insulating layer (864); and
forming a second external wiring layer (25C), which connects the first front surface side via (25A) and the second front surface side via (25B), on the fourth front surface side insulating layer (864).

### [Supplementary Note 30]

A method of manufacturing a semiconductor device (14), including:
forming a substrate side insulating layer (850) on a substrate (830);
forming a first front surface side insulating layer (861) on the substrate side insulating layer (850);
forming a first external wiring layer (24C) on the first front surface side insulating layer (861);
forming a second front surface side insulating layer (862) on the first front surface side insulating layer (861) so as to cover the first external wiring layer (24C);
forming a first substrate side via (24A) and a second substrate side via (24B), which are connected to the first external wiring layer (24C), in the second front surface side insulating layer (862);
forming a substrate side resistance layer (22) on the second front surface side insulating layer (862);
forming a third front surface side insulating layer (863) on the second front surface side insulating layer (862) so as to cover the substrate side resistance layer (22);
forming an internal via (23D), which is connected to the substrate side resistance layer (22), in the third front surface side insulating layer (863);
forming a front surface side resistance layer (21) on the third front surface side insulating layer (863);
forming a fourth front surface side insulating layer (864) on the third front surface side insulating layer (863) so as to cover the front surface side resistance layer (21);
forming a first front surface side via (25A) and a second front surface side via (25B), which are connected to the front surface side resistance layer (21), in the fourth front surface side insulating layer (864); and
forming a second external wiring layer (25C), which connects the first front surface side via (25A) and the second front surface side via (25B), on the fourth front surface side insulating layer (864).

### [Supplementary Note 31]

A method of manufacturing a semiconductor device (14), including:
forming a substrate side insulating layer (850) on a substrate (830);
forming a first front surface side insulating layer (861) and a second front surface side insulating layer (862) sequentially on the substrate side insulating layer (850);
forming a substrate side resistance layer (22) and a connection wiring layer (70) on the second front surface side insulating layer (862);
forming a third front surface side insulating layer (863) on the second front surface side insulating layer (862) so as to cover the substrate side resistance layer (22);
forming an internal via (23D), which is connected to the substrate side resistance layer (22), in the third front surface side insulating layer (863);
forming a front surface side resistance layer (21) on the third front surface side insulating layer (863);
forming a fourth front surface side insulating layer (864) on the third front surface side insulating layer (863) so as to cover the front surface side resistance layer (21);
forming a first front surface side via (25A) and a second front surface side via (25B), which are connected to the front surface side resistance layer (21), in the fourth front surface side insulating layer (864); and
forming a second external wiring layer (25C), which connects the first front surface side via (25A) and the second front surface side via (25B), on the fourth front surface side insulating layer (864).

### [Supplementary Note 32]

A method of manufacturing a semiconductor device (14), including:
forming a substrate side insulating layer (850) on a substrate (830);
forming a first front surface side insulating layer (861) and a second front surface side insulating layer (862) sequentially on the substrate side insulating layer (850);
forming a substrate side resistance layer (22) and a first connection wiring layer (71) on the second front surface side insulating layer (862);
forming a third front surface side insulating layer (863) on the second front surface side insulating layer (862) so as to cover the substrate side resistance layer (22);
forming an internal via (23D), which is connected to the substrate side resistance layer (22), in the third front surface side insulating layer (863);
forming a front surface side resistance layer (21) and a second connection wiring layer (72) on the third front surface side insulating layer (863); and
forming a fourth front surface side insulating layer (864) on the third front surface side insulating layer (863) so as to cover the front surface side resistance layer (21).

The above description is merely an example. Those skilled in the art will appreciate that more possible combinations and substitutions are possible beyond the components and methods (manufacturing processes) listed for the purposes of illustrating the techniques of the present disclosure. The present disclosure is intended to cover all alternatives, modifications, and changes that fall within the scope of the present disclosure, including the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a substrate;
an element insulating layer provided on the substrate; and
a semiconductor resistance layer provided on the element insulating layer,
wherein the semiconductor resistance layer includes:
a front surface side resistance layer extending in a first direction perpendicular to a thickness direction of the substrate;
a substrate side resistance layer arranged closer to the substrate than the front surface side resistance layer in the thickness direction; and
an internal connector that electrically connects the front surface side resistance layer and the substrate side resistance layer in series.

2. The semiconductor device of claim 1, wherein the substrate side resistance layer includes an overlap region that overlaps with the front surface side resistance layer when viewed from the thickness direction.

3. The semiconductor device of claim 2, wherein the overlap region is formed over an entirety of the substrate side resistance layer in the first direction.

4. The semiconductor device of claim 1, wherein in the first direction, the front surface side resistance layer is longer than the substrate side resistance layer.

5. The semiconductor device of claim 1, wherein the internal connector includes:
a first internal via connected to the front surface side resistance layer;
a second internal via provided at a different position from the first internal via in the first direction and connected to the substrate side resistance layer; and
an internal wiring layer arranged at a different position from both the front surface side resistance layer and the substrate side resistance layer in the thickness direction and connected to both the first internal via and the second internal via.

6. The semiconductor device of claim 2, wherein the internal connector includes an internal via connected to both the front surface side resistance layer and the overlap region of the substrate side resistance layer.

7. The semiconductor device of claim 6, wherein both the front surface side resistance layer and the substrate side resistance layer have a first end portion and a second end portion, which are both end portions in the first direction, and
wherein the internal via connects the second end portions of the front surface side resistance layer and the substrate side resistance layer in the first direction.

8. The semiconductor device of claim 1, wherein the semiconductor resistance layer includes a plurality of semiconductor resistance layers arranged to be spaced apart from one another in a second direction perpendicular to the first direction when viewed from the thickness direction,
wherein the plurality of semiconductor resistance layers includes a first semiconductor resistance layer, a second semiconductor resistance layer, and a third semiconductor resistance layer, which are adjacent to one another in the second direction, and
wherein the semiconductor device further comprises:
a first external connector that electrically connects the substrate side resistance layer of the first semiconductor resistance layer and the substrate side resistance layer of the second semiconductor resistance layer, which are adjacent to each other in the second direction; and
a second external connector that electrically connects the front surface side resistance layer of the second semiconductor resistance layer and the front surface side resistance layer of the third semiconductor resistance layer, which are adjacent to each other in the second direction.

9. The semiconductor device of claim 8, wherein the first external connector includes:
a first substrate side via connected to the substrate side resistance layer of the first semiconductor resistance layer;
a second substrate side via connected to the substrate side resistance layer of the second semiconductor resistance layer; and
a first external wiring layer extending in the second direction and connected to both the first substrate side via and the second substrate side via.

10. The semiconductor device of claim 8, wherein the second external connector includes:
a first front surface side via connected to the front surface side resistance layer of the second semiconductor resistance layer;
a second front surface side via connected to the front surface side resistance layer of the third semiconductor resistance layer; and
a second external wiring layer extending in the second direction and connected to both the first front surface side via and the second front surface side via.

11. The semiconductor device of claim 8, wherein both the front surface side resistance layer and the substrate side resistance layer have a first end portion and a second end portion, which are both end portions in the first direction,
wherein the internal connector is provided at the second end portion of the front surface side resistance layer and the second end portion of the substrate side resistance layer, and
wherein both the first external connector and the second external connector are located closer to the first end portion than a center of the semiconductor resistance layer in the first direction.

12. The semiconductor device of claim 10, wherein the second external connector is located on an opposite side to the substrate side resistance layer with respect to the front surface side resistance layer in the thickness direction.

13. The semiconductor device of claim 12, wherein both the front surface side resistance layer and the substrate side resistance layer have a first end portion and a second end portion, which are both end portions in the first direction, and
wherein the first external connector and the second external connector are provided so as to overlap with each other when viewed from the thickness direction at the first end portion of the front surface side resistance layer.

14. The semiconductor device of claim 8, wherein the first external connector is provided at the same position as the substrate side resistance layer of the first semiconductor resistance layer and the substrate side resistance layer of the second semiconductor resistance layer in the thickness direction, and includes a connection wiring layer that connects both the substrate side resistance layers.

15. The semiconductor device of claim 8, wherein the first external connector is provided at the same position as the substrate side resistance layer of the first semiconductor resistance layer and the substrate side resistance layer of the second semiconductor resistance layer in the thickness direction, and includes a first connection wiring layer that connects both the substrate side resistance layers, and
wherein the second external connector is provided at the same position as the front surface side resistance layer of the second semiconductor resistance layer and the front surface side resistance layer of the third semiconductor resistance layer in the thickness direction, and includes a second connection wiring layer that connects both the front surface side resistance layers.

16. The semiconductor device of claim 15, wherein both the front surface side resistance layer and the substrate side resistance layer have a first end portion and a second end portion, which are both end portions in the first direction, and
wherein the first connection wiring layer and the second connection wiring layer are provided at positions overlapping with each other when viewed from the thickness direction at the first end portion of the front surface side resistance layer.

17. The semiconductor device of claim 1, wherein in the first direction, a length of the front surface side resistance layer and a length of the substrate side resistance layer are equal to each other.

18. The semiconductor device of claim 1, wherein when viewed from the thickness direction, a width dimension of the front surface side resistance layer and a width dimension of the substrate side resistance layer are equal to each other.

19. The semiconductor device of claim 1, wherein a thickness of the front surface side resistance layer and a thickness of the substrate side resistance layer are equal to each other.

20. The semiconductor device of claim 1, wherein the element insulating layer includes:
a substrate side insulating layer provided on the substrate; and
a front surface side insulating layer stacked on the substrate side insulating layer,
wherein the substrate side insulating layer has a structure in which a plurality of first insulating films and a plurality of second insulating films that relieves a stress of the first insulating films are alternately stacked one by one, and
wherein the semiconductor resistance layer is embedded in the front surface side insulating layer.
